(19) United States
(12) Patent Application Publication
(10) Pub. No.: US 2024/0243115 A1
(43) Pub. Date: Jul. 18, 2024

(54) DISPLAY DEVICE AND METHOD OF FABRICATING THE SAME

(71) Applicant: Samsung Display Co., LTD., Yongin-si (KR)

(72) Inventors: Jin Woo CHOI, Yongin-si (KR); Hyung II JEON, Yongin-si (KR)

(21) Appl. No.: 18/411,543

(22) Filed: Jan. 12, 2024

(30) Foreign Application Priority Data
Jan. 16, 2023 (KR) 10-2023-0005937

(51) Int. Cl. H01L 25/16; H01L 33/00; H01L 33/08

(52) U.S. Cl. CPC H01L 25/167; H01L 33/0095; H01L 33/08; H01L 33/007; H01L 33/0093

(57) ABSTRACT

A display device includes pixel electrodes on a substrate, light-emitting elements on the pixel electrodes, a planarization layer on the pixel electrodes to fill a space between the light-emitting elements, and a common electrode on the planarization layer and the light-emitting elements, wherein each of the light-emitting elements includes a first light-emitting element stack and a second light-emitting element stack on the first light-emitting element stack.

### CROSS-REFERENCE TO RELATED APPLICATION

This application claims priority to and the benefit of Korean Patent Application No. 10-2023-0005937 filed on Jan. 16, 2023, in the Korean Intellectual Property Office, the entire disclosure of which is incorporated by reference herein.

### BACKGROUND

### 1. Field

The present disclosure relates to a display device and a method of fabricating the same.

### 2. Description of the Related Art

Display devices become more and more important as multimedia technology evolves. Accordingly, a variety of types of display devices such as organic light-emitting display (OLED) devices and liquid-crystal display (LCD) devices are currently used.

Display devices include a display panel such as an organic light-emitting display panel and a liquid-crystal display panel for displaying images. Among them, light-emitting display panel may include light-emitting elements. For example, light-emitting diodes (LEDs) may include an organic light-emitting diode (OLED) using an organic material as a luminescent material, and an inorganic light-emitting diode using an inorganic material as a luminescent material.

### SUMMARY

Aspects and features of the present disclosure provide a display device that can emit light without replacing or repairing a defective light-emitting element, and a method of fabricating a display device.

However, aspects and features of embodiments of the present disclosure are not restricted to the one set forth herein. The above and other aspects of the present disclosure will become more apparent to one of ordinary skill in the art to which the present disclosure pertains by referencing the detailed description of the present disclosure given below.

According to one or more embodiments, a display device includes pixel electrodes on a substrate, light-emitting elements on the pixel electrodes, a planarization layer on the pixel electrodes to fill a space between the light-emitting elements and a common electrode on the planarization layer and the light-emitting elements, wherein each of the light-emitting elements includes a first light-emitting element stack and a second light-emitting element stack on the first light-emitting element stack.

The display device further includes a bonding layer between the first light-emitting element stack and the second light-emitting element stack.

The bonding layer includes indium tin oxide (ITO) or indium zinc oxide (IZO).

The first light-emitting element stack includes a first semiconductor layer, an electron blocking layer, an active layer, a superlattice layer, and a second semiconductor layer, and wherein the second light-emitting element stack includes a first semiconductor layer, an electron blocking layer, an active layer, a superlattice layer, a second semiconductor layer, and a third semiconductor layer.

The second semiconductor layer of the first light-emitting element stack is in contact with the first semiconductor layer of the second light-emitting element stack.

The light-emitting elements are randomly arranged on the pixel electrodes.

The display device further includes a wavelength-converting portion on the common electrode, wherein the wavelength-converting portion includes partition walls partitioning emission areas and a non-emission area, a wavelength conversion layer between the partition walls and overlapping with the emission areas, a light-blocking member on the partition walls and color filters on the wavelength conversion layer.

The display device further includes a reflective metal layer between the common electrode and the partition walls, wherein the reflective metal layer overlaps with the non-emission area.

According to one or more embodiments, a display device includes pixel electrodes on a substrate, light-emitting elements on the pixel electrodes, a planarization layer on the pixel electrodes to fill a space between the light-emitting elements and a common electrode on the planarization layer and the light-emitting elements, wherein the light-emitting elements have a tandem structure in which a plurality of light-emitting element stacks is stacked, and wherein each of the plurality of light-emitting element stacks includes a first semiconductor layer, an electron blocking layer, an active layer, a superlattice layer, and a second semiconductor layer.

The display device further includes a bonding layer between the plurality of light-emitting element stacks.

The bonding layer includes indium tin oxide (ITO) or indium zinc oxide (IZO).

The second semiconductor layer of a light-emitting element stack from among the plurality of light-emitting element stacks at a bottom is in contact with the first semiconductor layer of the light-emitting element stack at a top.

A top light-emitting element stack from among the plurality of light-emitting element stacks further includes a third semiconductor layer.

According to one or more embodiments, a method of fabricating a display device includes forming light-emitting elements on a base substrate, attaching the light-emitting elements onto pixel electrodes by bonding a substrate including the pixel electrodes to the base substrate, separating the base substrate from the light-emitting elements by irradiating a laser beam onto the base substrate, forming a planarization layer between the pixel electrodes and the light-emitting elements and forming a common electrode on the planarization layer, wherein the light-emitting elements include a first light-emitting element stack and a second light-emitting element stack on the first light-emitting element stack.

The forming the light-emitting elements on the base substrate includes forming a plurality of semiconductor material layers on a first base substrate, attaching the first base substrate to a temporary substrate, forming the first light-emitting element stack by separating the first base substrate from the plurality of semiconductor material layers, forming a first bonding layer on the first light-emitting element stack, forming the second light-emitting element stack by forming a plurality of semiconductor material layers on a second base substrate, forming a second bonding layer on the second light-emitting element stack, stacking the first light-emitting element stack on the second light-emitting element stack such that the first bonding layer and the second bonding layer are in contact with each other, and bonding the first bonding layer and the second bonding layer to each other, separating the temporary substrate from the first light-emitting element stack and forming the light-emitting elements by patterning the first light-emitting element stack stacked on the second light-emitting element stack using a photoresist pattern.

The method further includes forming a connection electrode on the light-emitting elements.

The forming the plurality of semiconductor material layers on the first base substrate includes forming a third semiconductor material layer, a second semiconductor material layer, a superlattice material layer, an active material layer, an electron blocking material layer, and a first semiconductor material layer on the first base substrate in this order.

The forming the first light-emitting element stack by separating the first base substrate from the plurality of semiconductor material layers includes irradiating the base substrate with a laser, separating the first base substrate from the plurality of semiconductor material layers, and etching the third semiconductor material layer to remove it.

The forming the second light-emitting element stack by forming the plurality of semiconductor material layers on the second base substrate includes forming a third semiconductor material layer, a second semiconductor material layer, a superlattice material layer, an active material layer, an electron blocking material layer, and a first semiconductor material layer on the second base substrate in this order.

The stacking the first light-emitting element stack on the second light-emitting element stack such that the first bonding layer and the second bonding layer are in contact with each other, and bonding the first bonding layer and the second bonding layer to each other includes oxide bonding the first bonding layer and the second bonding layer to each other.

The forming the light-emitting elements on the base substrate includes forming a third semiconductor material layer, a second semiconductor material layer, a superlattice material layer, an active material layer, an electron blocking material layer and a first semiconductor material layer of a second light-emitting element stack on the base substrate in this order, forming a third semiconductor material layer, a second semiconductor material layer, a superlattice material layer, an active material layer, an electron blocking material layer and a first semiconductor material layer of the first light-emitting element stack on the second light-emitting element stack and forming the light-emitting elements by patterning the second light-emitting element stack and the first light-emitting element stack using a photoresist pattern.

According to one or more embodiments of the present disclosure, light-emitting elements are formed in a tandem structure in a display device, and thus even if there is a short-circuit in one of top and bottom light-emitting element stacks of a light-emitting element, the light-emitting element can still emit light. Therefore, no repair is required for a light-emitting element in which a short circuit is created.

However, the effects of the present disclosure are not limited to the aforementioned effects, and various other effects are included in the present specification.

### BRIEF DESCRIPTION OF THE DRAWINGS

The above and other aspects and features of the present disclosure will become more apparent by describing in detail embodiments thereof with reference to the attached drawings, in which:

FIG. 1 is a plan view of a display device according to one or more embodiments of the present disclosure.

FIG. 2 is a view showing a layout of a circuit of a display substrate of a display device according to one or more embodiments.

FIG. 3 is an equivalent circuit diagram of a pixel of a display device according to one or more embodiments of the present disclosure.

FIG. 4 is a layout diagram showing sub-pixels of the display area of the display panel according to one or more embodiments.

FIG. 5 is a cross-sectional view showing an example of the display panel taken along the line Q1-Q1′ of FIG. 4.

FIG. 6 is an enlarged view of an area B of FIG. 5 according to one or more embodiments.

FIG. 7 is an enlarged view of an area B of FIG. 5 according to one or more embodiments.

FIG. 8 is a plan view schematically showing a plurality of emission areas and a plurality of color filters.

FIG. 9 is a plan view showing a modification of the emission areas of the display device according to one or more embodiments.

FIG. 10 is a cross-sectional view showing a display device according to one or more embodiments of the present disclosure.

FIG. 11 is a cross-sectional view showing a display device according to one or more embodiments.

FIG. 12 is a cross-sectional view schematically showing a display device according to one or more embodiments.

FIG. 13 is a plan view schematically showing a plurality of emission areas and a reflective metal layer according to one or more embodiments.

FIG. 14 is a flowchart for illustrating a method of fabricating a display device according to one or more embodiments of the present disclosure.

FIG. 15 is a flowchart for illustrating in more detail step S100 of FIG. 14.

FIGS. 16 to 36 are views for illustrating a method of fabricating a display device according to one or more embodiments of the present disclosure.

FIG. 37 is a view for illustrating step S100 of FIG. 14 according to one or more embodiments.

FIG. 38 is an example diagram schematically showing a virtual reality device including a display device according to one or more embodiments.

FIG. 39 is an example diagram schematically showing a smart device including a display device according to one or more embodiments.

FIG. 40 is a diagram of an example schematically showing a vehicle including a display device according to one or more embodiments.

FIG. 41 is a diagram of an example schematically showing a transparent display device including a display device according to one or more embodiments.

### DETAILED DESCRIPTION

The present disclosure will now be described more fully hereinafter with reference to the accompanying drawings, in which embodiments of the present disclosure are shown. The present disclosure may, however, be embodied in different forms and should not be construed as limited to the embodiments set forth herein. Rather, these embodiments are provided so that the present disclosure will be thorough and complete, and will fully convey the scope of the present disclosure to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” and the like may be used herein to describe various elements, these elements should not be limited by these terms. These terms are only used to distinguish one element from another element. For instance, a first element discussed below could be termed a second element without departing from the teachings and scope of the present disclosure. Similarly, the second element could also be termed the first element.

Each of the features of the various embodiments of the present disclosure may be combined or combined with each other, in part or in whole, and technically various interlocking and driving are possible. Each embodiment may be implemented independently of each other or may be implemented together in an association.

Hereinafter, embodiments of the present disclosure will be described in detail with reference to the accompanying drawings.

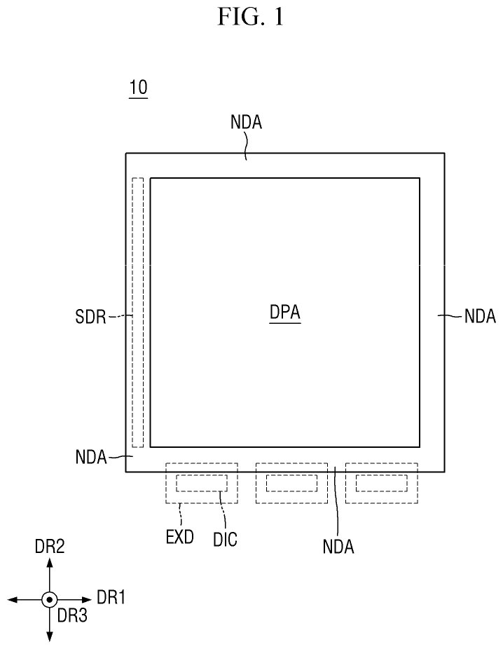

FIG. 1 is a plan view of a display device according to one or more embodiments of the present disclosure.

Referring to FIG. 1, a display device 10 according to one or more embodiments of the present disclosure may be applied to, a smart phone, a mobile phone, a tablet PC, a personal digital assistant (PDA), a portable multimedia player (PMP), a television set, a game machine, a wristwatch-type electronic device, a head-mounted display, a personal computer monitor, a laptop computer, a car navigation system, a car instrument cluster, a digital camera, a camcorder, an outdoor billboard, an electronic billboard, various medical apparatuses, various home appliances such as a refrigerator and a laundry machine, Internet of things (IoT) devices, etc. In the following description, a television is described as an example of the display device. TV may have a high resolution or ultra high resolution such as HD, UHD, 4K and 8K.

In addition, the display device 10 according to one or more embodiments may be variously classified by the way in which images are displayed. Examples of the classification of display devices may include an organic light-emitting diode (OLED) display device, an inorganic light-emitting display device (inorganic EL), a quantum-dot light-emitting diode (QD-LED) display device (QED), a micro LED display device (micro-LED), a nano LED display device (nano-LED), a plasma display device (PDP), a field emission display (FED) device, a cathode ray tube (CRT) display device, a liquid-crystal display (LCD) device, an electrophoretic display (EPD) device, etc. In the following description, an organic light-emitting display device will be described as an example of the display device, and the organic light-emitting display device will be simply referred to as a display device unless it is necessary to discern it from others. It is, however, to be understood that the embodiments of the present disclosure are not limited to the organic light-emitting display device, and one of the above-listed display devices or any other display device well known in the art may be employed without departing from the teachings and scope of the present disclosure.

In addition, in the drawings, a first direction DR1 refers to the horizontal direction of a display device 10, a second direction DR2 refers to the vertical direction of the display device 10, and a third direction DR3 refers to the thickness direction of the display device 10. As used herein, the terms “left,” “right,” “upper” and “lower” sides refer to relative positions when the display device 10 is viewed from the top. For example, the right side refers to one side in the first direction DR1, the left side refers to the other side in the first direction DR1, the upper side refers to one side in the second direction DR2, and the lower side refers to the other side in the second direction DR2. In addition, the upper portion refers to the side indicated by the arrow of the third direction DR3, while the lower portion refers to the opposite side in the third direction DR3.

According to one or more embodiments of the present disclosure, the display device 10 may have a quadrate shape, e.g., a square shape when viewed from the top. When the display device 10 is a television, it may have a rectangular shape in which the longer sides are located in the horizontal direction. It should be understood, however, that the present disclosure is not limited thereto. The longer side may be positioned in the vertical direction. Alternatively, the display device 10 may be installed rotatably so that the longer sides are positioned in the horizontal or vertical direction variably. In addition, the display device 10 may have a circular or elliptical shape.

The display device 10 may include a display area DPA and a non-display area NDA. The display area DPA may be an active area where images are displayed. The display area DPA may have, but is not limited to, a square shape similar to the general shape of the display device 10 when viewed from the top.

The non-display area NDA may be disposed around the display area DPA along an edge or periphery of the display area DPA. The non-display area NDA may surround the display area DPA entirely or partially. The display area DPA may have a square shape, and the non-display area NDA may be disposed to be adjacent to the four sides of the display area DPA. The non-display area NDA may form the bezel of the display device 10.

In the non-display areas NDA, a driving circuit or a driving element for driving the display area DPA may be disposed. According to one or more embodiments of the present disclosure, pad areas may be located on the display substrate of the display device 10 in the non-display area NDA adjacent to a first side (e.g., the lower side in FIG. 1) of the display device 10, and external devices EXD may be mounted on pad electrodes of the pad areas. Examples of the external devices EXD may include a connection film, a printed circuit board, a driver chip DIC, a connector, a line connection film, etc. A scan driver SDR formed directly on the display substrate of the display device 10 or the like may be disposed in the non-display area NDA adjacent to a second side (e.g., the left side in FIG. 1) of the display device 10.

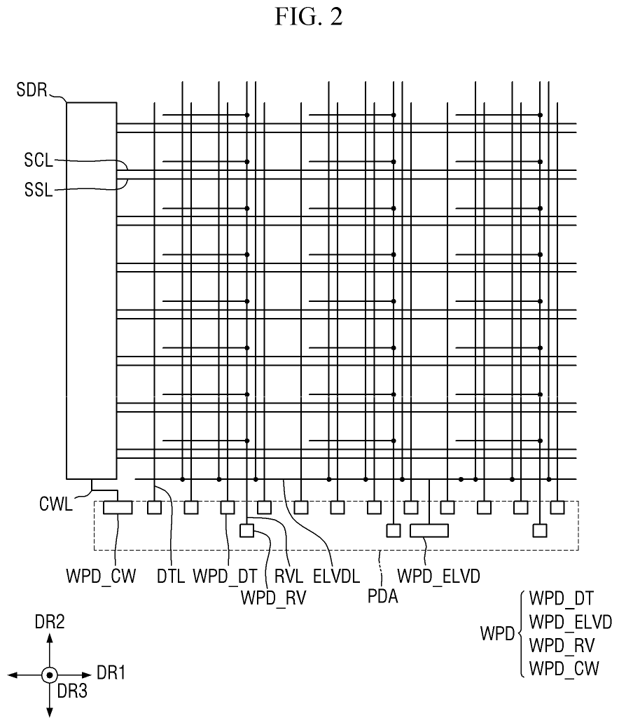

FIG. 2 is a view showing a layout of a circuit of a display substrate of a display device according to one or more embodiments.

Referring to FIG. 2, a plurality of lines is disposed on the first substrate. The plurality of lines may include a scan line SCL, a sensing signal line SSL, a data line DTL, a reference voltage line RVL, a first supply voltage line ELVDL, etc.

The scan line SCL and the sensing signal line SSL may be extended in the first direction DR1. The scan line SCL and the sensing signal line SSL may be connected to the scan driver SDR. The scan driver SDR may include a driving circuit. The scan driver SDR may be disposed on one side of the non-display area NDA on the display substrate, but the present disclosure is not limited thereto. The scan driver SDR may be disposed on both sides of the non-display area NDA. The scan driver SDR may be connected to a signal connection line CWL. At least one end of the signal connection line CWL may form a pad WPD_CW on the first non-display area NDA and/or the second non-display area NDA and may be connected to an external device EXD (see FIG. 1).

The data line DTL and the reference voltage line RVL may be extended in the second direction DR2 crossing the first direction DR1. A first supply voltage line ELVDL may include a portion extending in the second direction DR2. The first supply voltage line ELVDL may further include a portion extending in the first direction DR1. The first supply voltage line ELVDL may have, but is not limited to, a mesh structure.

The wire pads WPD may be disposed at at least one end of the data line DTL, the reference voltage line RVL, and the first supply voltage line ELVDL. The wire pads WPD may be disposed in the pad area PDA of the non-display area NDA. According to one or more embodiments of the present disclosure, a wire pad WPD_DT of the data line DTL (hereinafter referred to as a data pad), a wire pad WPD_RV of the reference voltage line RVL (hereinafter referred to as a reference voltage pad), and a wire pad WPD_ELVD of the first supply voltage line ELVDL (hereinafter referred to as a first supply voltage pad) may be disposed in the pad area PDA of the non-display area NDA. As another example, the data pad WPD_DT, the reference voltage pad WPD_RV, and the first supply voltage pad WPD_ELVD may be disposed in different non-display areas NDA. As described above, the external devices EXD (see FIG. 1) may be mounted on the wire pad WPD. The external devices EXD may be mounted on the wire pads WPD by an anisotropic conductive film, ultrasonic bonding, etc.

Each of the pixels on the display substrate includes a pixel driving circuit. The above-described lines may pass through each of the pixels or the periphery thereof to apply a driving signal to the pixel driving circuit. The pixel driving circuit may include transistors and a capacitor. The numbers of transistors and capacitors of each pixel driving circuit may be changed in a variety of ways. In the following description, the pixel driving circuit having a 3T1C structure including three transistors and one capacitor will be described as an example. It is, however, to be understood that the present disclosure is not limited thereto. A variety of modified pixel structure may be employed such as a 2T1C structure, a 7T1C structure, and/or a 6T1C structure.

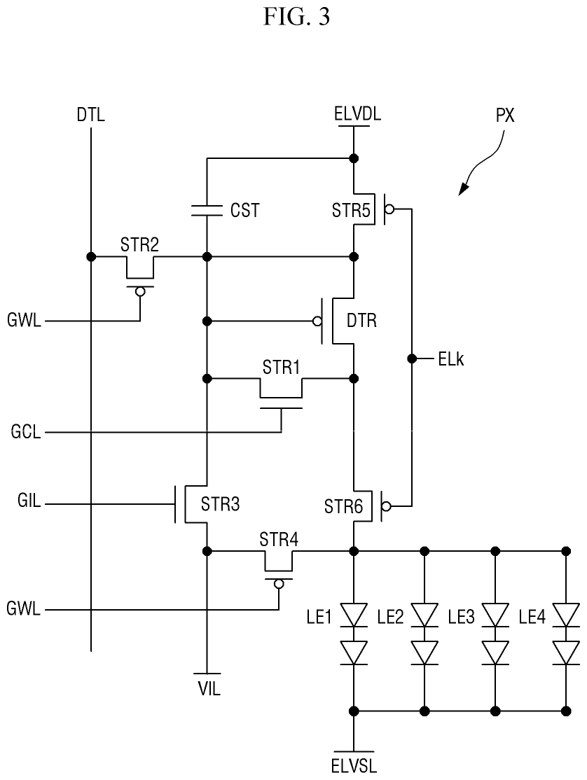

FIG. 3 is an equivalent circuit diagram of a pixel of a display device according to one or more embodiments of the present disclosure.

Referring to FIG. 3, each of the pixels PX of the display device according to one or more embodiments includes a driving transistor DTR, switching elements and a capacitor CST in addition to a plurality of light-emitting elements LE1, LE2, LE3, and LE4. The switching elements may include first to sixth transistors STR1, STR2, STR3, STR4, STR5 and STR6, and one storage capacitor CST.

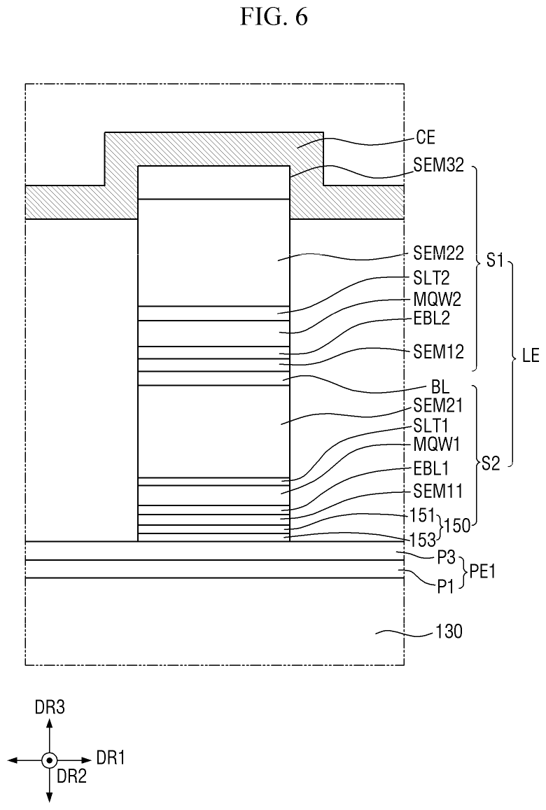

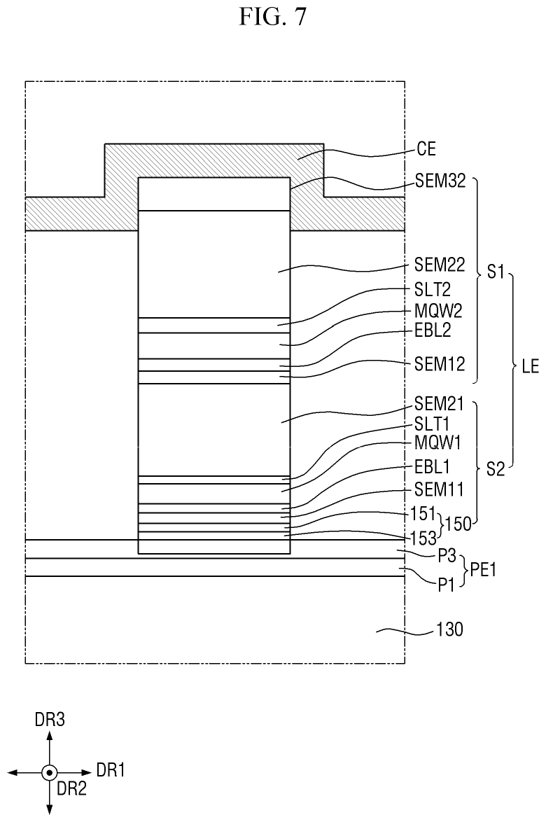

The first electrodes of the light-emitting element LE1, LE2, LE3 and LE4 may be connected to the first electrode of the fourth transistor STR4 and the second electrode of the sixth transistor STR6, while the second electrode may be connected to the second supply voltage line ELVSL. The light-emitting elements have a tandem structure and connected to one another in series and parallel. The light-emitting elements of the tandem structure will be described later with reference to FIGS. 6 and 7. Although four light-emitting elements LE1, LE2, LE3 and LE4 are shown in the example of FIG. 3, this is merely illustrative.

The driving transistor DTR includes a gate electrode, a first electrode, and a second electrode. A drain-source current Ids (hereinafter referred to as “driving current”) of driving transistor DTR flowing between the first electrode and the second electrode is controlled according to the data voltage applied to the gate electrode.

The capacitor CST is formed between the first electrode of the driving transistor DTR and the first supply voltage line ELVDL. One electrode of the capacitor CST may be connected to the first electrode of the driving transistor DTR while the other electrode thereof may be connected to the first voltage supply line ELVDL.

The driving transistor DTR, the second transistor STR2, the fourth transistor STR4, the fifth transistor STR5 and the sixth transistor STR6 may be implemented as p-type MOSFETs (PMOS) while the first transistor STR1 and the third transistor STR3 may be implemented as n-type MOSFETs (NMOS).

The active layer of each of the driving transistor DRT, the second transistor STR2, the fourth transistor STR4, the fifth transistor STR5 and the sixth transistor STR6 implemented as p-type MOSFETs may be made of polysilicon, and the active layer of the first transistor STR1 and the third transistor STR3 implemented as n-type MOSFETs may be made of oxide semiconductor.

The gate electrode of the second transistor STR2 and the gate electrode of the fourth transistor STR4 are connected to a write scan line GWL, and the gate electrode of the first transistor STR1 is connected to a control scan line GCL.

Because the first transistor STR1 and the third transistor STR3 are implemented as n-type MOSFETs, a scan signal of a gate-high voltage may be applied to the control scan line GCL and an initialization scan line GIL. In contrast, because the second transistor STR2, the fourth transistor STR4, the fifth transistor STR5, and the sixth transistor STR6 are formed of p-type MOSFETs, a scan signal of a gate-low voltage may be applied to the write scan line GWL and an emission line EL.

A first electrode of the driving transistor DTR may be connected to a second electrode of the fifth transistor STR5 and a second electrode of the driving transistor DTR may be connected to a first electrode of the sixth transistor STR6.

The first transistor STR1 may be connected between the gate electrode and the second electrode of the driving transistor DTR, and the gate electrode of the first transistor STR1 is connected to the control scan line GCL.

The second transistor STR2 is connected between a data line DTL and the first electrode of the driving transistor DTR, and the gate electrode of the second transistor STR2 may be connected to the write scan line GWL.

The third transistor STR3 may be connected between the gate electrode of the driving transistor DTR and an initialization voltage line VIL. The gate electrode of the third transistor STR3 may be connected to an initialization scan line GIL.

The fourth transistor STR4 may be coupled between the initialization voltage line VIL and the second electrode of the sixth transistor STR6 which is connected to the light-emitting elements LE1, LE2, LE3 and LE4. The gate electrode of the fourth transistor STR4 may be connected to the write scan line GWL.

The fifth transistor STR5 may be connected between the first voltage supply line ELVDL and the first electrode of the driving transistor DTR and a sixth transistor STR6 may be connected between a second electrode of the driving transistor DTR and light-emitting elements LE1, LE2, LE3 and LE4. Gate electrodes of the fifth transistor STR5 and the sixth transistor STR6 may be connected to a kth emission line Elk.

It should be noted that the equivalent circuit diagram of the pixels according to one or more embodiments of the present disclosure is not limited to that shown in FIG. 3. The equivalent circuit diagram of the pixels according to one or more embodiments of the present disclosure may be implemented as any other circuit structures known in the art than that of the embodiment shown in FIG. 3.

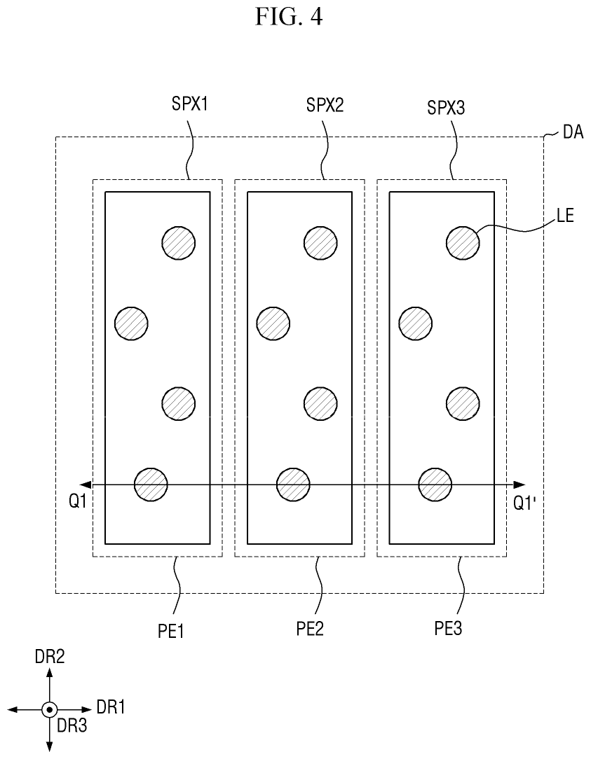

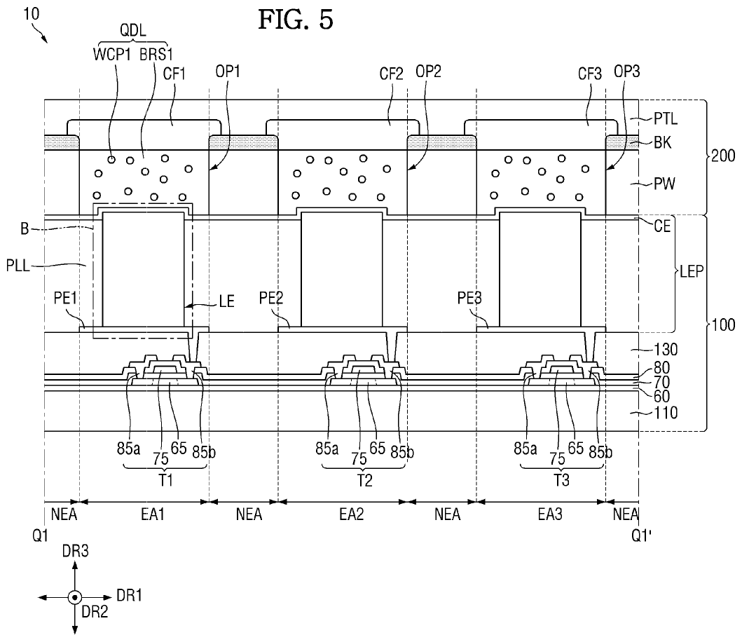

FIG. 4 is a layout diagram showing sub-pixels of the display area of the display panel according to one or more embodiments. FIG. 5 is a cross-sectional view showing an example of the display panel taken along the line Q1-Q1′ of FIG. 4. FIG. 6 is an enlarged view of an area B of FIG. 5 according to one or more embodiments. FIG. 7 is an enlarged view of an area B of FIG. 5 according to one or more embodiments.

Referring to FIGS. 4 to 6, the display area DA may include a plurality of pixels. Each of the pixels may include a first sub-pixel SPX1, a second sub-pixel SPX2, and a third sub-pixel SPX3.

In each of the pixels, the first sub-pixel SPX1, the second sub-pixel SPX2 and the third sub-pixel SPX3 may be arranged in the first direction DR1. In addition, the first sub-pixels SPX1 may be arranged in the second direction DR2, the second sub-pixels SPX2 may be arranged in the second direction DR2, and the third sub-pixels SPX3 may be arranged in the second direction DR2.

The sub-pixels SPX1, SPX2, and SPX3 may include pixel electrodes PE1, PE2, and PE3, respectively, and one or more light-emitting elements LE. Although the pixel electrodes PE1, PE2, and PE3 have a rectangular shape when viewed from the top in the example shown in the drawings, the present disclosure is not limited thereto.

The light-emitting elements LE may be arranged randomly on the pixel electrodes PE1, PE2, and PE3. According to one or more embodiments, the light-emitting elements LE may be aligned with a line extended in one direction. For example, they may be arranged in an oblique matrix, and the distance between rows and columns may be equally spaced apart from one another. In addition, the light-emitting elements LE may have the same arrangement on each of the pixel electrodes PE1, PE2, and PE3.

Referring to FIG. 5, the display device 10 may include a display substrate 100 and a wavelength-converting portion 200 disposed on the display substrate 100.

The display substrate 100 may include a first substrate 110 and a light-emitting element portion LEP disposed on the first substrate 110. The first substrate 110 may be an insulating substrate. The first insulating layer 110 may include a transparent material. For example, the first substrate 110 may include a transparent insulating material such as glass and/or quartz. The first substrate 110 may be a rigid substrate. However, the first substrate 110 is not limited to those described above. The first substrate 110 may include a plastic such as polyimide or may be flexible so that it can be curved, bent, folded, and/or rolled. A plurality of emission areas EA1, EA2, and EA3 and a non-emission area NEA may be defined in the first substrate 110.

On the first substrate 110, switching elements T1, T2, and T3 may be disposed. According to one or more embodiments of the present disclosure, the first switching element T1 may be located in the first emission area EA1, the second switching element T2 may be located in the second emission area EA2, and the third switching element T3 may be located in the third emission area EA3. It is, however, to be understood that the present disclosure is not limited thereto. In one or more embodiments, at least one of the first switching device T1, the second switching device T2, and/or the third switching device T3 may be located in the non-emission area NEA.

According to one or more embodiments of the present disclosure, each of the first switching element T1, the second switching element T2, and the third switching element T3 may be a thin-film transistor including amorphous silicon, polysilicon, and/or an oxide semiconductor. In one or more embodiments, a plurality of signal lines (for example, gate lines, data lines, power lines, etc.) for transmitting signals to the switching elements may be further disposed on the first substrate 110.

Each of the switching elements T1, T2, and T3 may include a semiconductor layer 65, a gate electrode 75, a source electrode 85a, and a drain electrode 85b. Specifically, a buffer layer 60 may be disposed on the first substrate 110. The buffer layer 60 may be disposed to cover the entire surface of the first substrate 110. The buffer layer 60 may include silicon nitride, silicon oxide, silicon oxynitride, etc., and may be made up of a single layer or a double layer thereof.

The semiconductor layer 65 may be disposed on the buffer layer 60. The semiconductor layer 65 may form a channel of each of the switching elements T1, T2, and T3. The semiconductor layer 65 may include amorphous silicon, polycrystalline silicon, and/or oxide semiconductor. The oxide semiconductor may include, for example, a binary compound (ABx), a ternary compound (ABxCy), and a quaternary compound (ABxCyDz) containing indium, zinc, gallium, tin, titanium, aluminum, hafnium (Hf), zirconium (Zr), magnesium (Mg), etc. According to one or more embodiments of the present disclosure, the semiconductor layer 65 may include indium tin zinc oxide (IGZO).

The gate insulating layer 70 may be disposed on the semiconductor layer 65 and the buffer layer 60. The gate insulator 70 may include a silicon compound, a metal oxide, etc. For example, the gate insulator 70 may include silicon oxide, silicon nitride, silicon oxynitride, aluminum oxide, tantalum oxide, hafnium oxide, zirconium oxide, titanium oxide, etc. According to one or more embodiments of the present disclosure, the gate insulating layer 70 may include silicon oxide.

The gate electrode 75 may be disposed on the gate insulating layer 70. The gate electrode 75 may be disposed to overlap the semiconductor layer 65 in a thickness direction of the first substrate 110 (e.g., a third direction DR3). The gate electrode 75 may include a conductive material. The gate electrode 75 may include a metal oxide such as ITO, IZO, ITZO, and In₂O₃, or a metal such as copper (Cu), titanium (Ti), aluminum (Al), molybdenum (Mo), tantalum (Ta), calcium (Ca), chromium (Cr), magnesium (Mg), and/or nickel (Ni). For example, the gate electrode 75 may include, but is not limited to, a double layer of Cu/Ti in which an upper layer of copper is stacked on a lower layer of titanium.

The interlayer dielectric layer 80 may be disposed on the gate electrode 75 and the gate insulating layer 70. The interlayer dielectric layer 80 may include an inorganic insulating material such as silicon oxide, silicon nitride, silicon oxynitride, hafnium oxide, aluminum oxide, titanium oxide, tantalum oxide, and/or zinc oxide.

A source electrode 85a and a drain electrode 85b may be disposed on the interlayer dielectric layer 80. The source electrode 85a and the drain electrode 85b may be in contact with the semiconductor layer 65 through respective contact holes penetrating the interlayer dielectric layer 80 and the gate insulator 70. The source electrode 85a and the drain electrode 85b may include a metal oxide such as ITO, IZO, ITZO, and In₂O₃, or a metal such as copper (Cu), titanium (Ti), aluminum (Al), molybdenum (Mo), tantalum (Ta), calcium (Ca), chromium (Cr), magnesium (Mg), and/or nickel (Ni). For example, the source electrode 85a and the drain electrode 85b may include, but is not limited to, a double layer of Cu/Ti in which an upper layer of copper is stacked on a lower layer of titanium.

An insulating layer 130 may be disposed over the first switching element T1, the second switching element T2, and the third switching element T3. According to one or more embodiments of the present disclosure, the insulating layer 130 may be a planarization layer and may include an organic material. For example, the insulating layer 130 may include an acrylic resin, an epoxy resin, an imide resin, an ester resin, etc. According to one or more embodiments of the present disclosure, the insulating layer 130 may include a positive photosensitive material or a negative photosensitive material.

The light-emitting element portion LEP may be disposed on the insulating layer 130. The light-emitting element portion LEP may include a plurality of pixel electrodes PE1, PE2, and PE3, a plurality of light-emitting elements LE, and a common electrode CE.

The plurality of pixel electrodes PE1, PE2, and PE3 may include a first pixel electrode PE1, a second pixel electrode PE2, and a third pixel electrode PE3. The first pixel electrode PE1, the second pixel electrode PE2, and the third pixel electrode PE3 may work as a first electrode of the light-emitting element LE and may be an anode electrode or a cathode electrode. The first pixel electrode PE1 may be located in the first emission area EA1, the second pixel electrode PE2 may be located in the second emission area EA2, and the third pixel electrode PE3 may be located in the third emission area EA3. According to one or more embodiments of the present disclosure, the first pixel electrode PE1 may completely overlap with in the first emission area EA1, the second pixel electrode PE2 may completely overlap with the second emission area EA2, and the third pixel electrode PE3 may completely overlap with the third emission area EA3. The first pixel electrode PE1 may be connected to the first switching element T1 through the insulating layer 130, the second pixel electrode PE2 may be connected to the second switching element T2 through the insulating layer 130, and the third pixel electrode PE3 may be connected to the third switching element T3 through the insulating layer 130.

The first pixel electrode PE1, the second pixel electrode PE2, and the third pixel electrode PE3 may include a metal. The metal may include, for example, copper (Cu), titanium (Ti), silver (Ag), magnesium (Mg), aluminum (Al), platinum (Pt), lead (Pd), gold (Au), nickel (Ni), neodymium (Nd), iridium (Ir), chromium (Cr), lithium (Li), calcium (Ca), and/or a mixture thereof. In addition, the first pixel electrode PE1, the second pixel electrode PE2, and the third pixel electrode PE3 may have a multi-layer structure in which two or more metal layers are stacked. For example, the first pixel electrode PE1, the second pixel electrode PE2, and the third pixel electrode PE3 may have, but is not limited to, a two-layer structure in which a copper layer is stacked on a titanium layer.

Referring to FIG. 6, according to present embodiment, the pixel electrode PE1 may include a lower electrode layer P1 and an upper electrode layer P3. In the following description, the first pixel electrode PE1 will be described as an example. It is to be understood that the second pixel electrode PE2 and the third pixel electrode PE3 are similar thereto.

The lower electrode layer P1 may be disposed at the bottom of the first pixel electrode PE1 and may be electrically connected from the switching element. The lower electrode layer P1 may provide the first pixel electrode PE1 with adhesiveness to be coupled to the insulating layer 130. The lower electrode layer P1 may include metal, for example, titanium.

The upper electrode layer P3 may be disposed on the lower electrode layer P1 and may be in direct contact with the light-emitting element LE. The upper electrode layer P3 may be disposed between the lower electrode layer P1 and the light-emitting element LE, and may provide the first pixel electrode PE1 with adhesiveness to be coupled to the light-emitting element LE. The upper electrode layer P3 may include a metal, for example, copper.

A plurality of light-emitting elements LE may be disposed on the first pixel electrode PE1, the second pixel electrode PE2, and the third pixel electrode PE3.

As shown in FIGS. 5 and 6, the light-emitting elements LE may be disposed in each of the first emission area EA1, the second emission area EA2, and the third emission area EA3. Each of the light-emitting elements LE may be a vertical light-emitting diode extended in the third direction DR3. That is to say, the length of the light-emitting element LE in the third direction DR3 may be greater than the length in the horizontal direction. The horizontal length refers to either the length in the first direction DR1 or the length in the second direction DR2. For example, the length of the light-emitting element LE in the third direction DR3 may be approximately 1 to 5 μm.

Each of the light-emitting elements LE may be a micro light-emitting diode. The light-emitting elements LE may have a cylindrical shape, a disk shape, or a rod shape having the width longer than the height. It should be understood, however, that the present disclosure is not limited thereto. The light-emitting element LE may have a shape of a rod, wire, tube, etc., a shape of a polygonal column such as a cube, a cuboid, and/or a hexagonal column, or may have a shape extended in a direction with partially inclined outer surface.

The light-emitting element LE includes a connection electrode 150, a first light-emitting element stack S1, a bonding layer BL, and a second light-emitting element stack S2 in the thickness direction of the display substrate 100, i.e., in the third direction DR3. The connection electrode 150, the first light-emitting element stack S1, the bonding layer BL, and the second light-emitting element stack S2 may be stacked in this order in the third direction DR3.

The connection electrode 150 may be disposed on each of the plurality of pixel electrodes PE1, PE2, and PE3. Hereinafter, the light-emitting elements LE disposed on the first pixel electrode PE1 will be described as an example, but the present disclosure is not limited thereto. The light-emitting elements LE disposed on the second pixel electrode PE2 and the third pixel electrode PE3 may have the same structure.

The connection electrode 150 may include a reflective layer 151 and a connection layer 153. The reflective layer 151 may reflect light emitted from the active layer MQW (e.g., MQW1, MQW2) of the light-emitting element LE. The reflective layer 151 may be disposed adjacent to the active layer MQW (e.g., MQW1, MQW2) of the light-emitting element LE. The reflective layer 151 may include a metal material having high light reflectance while having conductivity. The reflective layer 151 may include, for example, aluminum (Al), silver (Ag), and/or an alloy thereof.

The connection layer 153 may transmit an emission signal from the first pixel electrode PE1 to the light-emitting element LE. The connection layer 153 may be an ohmic connection electrode. It is, however, to be understood that the present disclosure is not limited thereto. The connection layer 153 may be a Schottky connection electrode. The connection layer 153 may be disposed at the bottom of the light-emitting element LE and may be disposed farther from the active layer MQW (e.g., MQW1, MQW2) than the reflective layer 151 is. The connection layer 153 may include at least one of gold (Au), copper (Cu), tin (Sn), silver (Ag), aluminum (Al), and titanium (Ti). For example, the connection layer 153 may include a 9:1 alloy, an 8:2 alloy, and/or a 7:3 alloy of gold and tin, and/or an alloy of copper, silver and tin (SAC305).

Although the connection electrode 150 of the light-emitting element LE has a double-layer structure of one reflective layer 151 and a connection layer 153 in the example shown in FIG. 6, the present disclosure is not limited thereto. In one or more embodiments, the light-emitting element LE may include the connection electrode 150 having more than two layers, or some layers may be eliminated therefrom.

The first light-emitting element stack S1 may include a first semiconductor layer SEM11, an electron blocking layer EBL1, an active layer MQW1, a superlattice layer SLT1, and a second semiconductor layer SEM21. The first semiconductor layer SEM11, the electron blocking layer EBL1, the active layer MQW1, the superlattice layer SLT1, and the second semiconductor layer SEM21 may be stacked on one another in this order in the third direction DR3.

The first semiconductor layer SEM11 may be disposed on the connection electrode 150. The first semiconductor layer SEM11 may be a p-type semiconductor, and may include a semiconductor material having the following chemical formula: AlₓGa_{y}In_{1-x-y}N (0≤x≤1, 0≤y≤1 and 0≤x+y≤1). For example, it may be at least one of p-type doped AlGaInN, GaN, AlGaN, InGaN, AlN, and InN. The first semiconductor layer SEM11 may be doped with a p-type dopant, and the p-type dopant may be Mg, Zn, Ca, Se, Ba, etc. For example, the first semiconductor layer SEM11 may be p-GaN doped with p-type Mg. The thickness of the first semiconductor layer SEM11 may range, but is not limited to, from 30 nm to 200 nm.

The electron blocking layer EBL1 may be disposed on the first semiconductor layer SEM11. The electron blocking layer EBL1 may suppress or prevent too many electrons from flowing into the active layer MQW1. For example, the electron blocking layer EBL1 may be p-AlGaN doped with p-type Mg. The thickness of the electron blocking layer EBL1 may be in a range of 10 nm to 50 nm, but the present disclosure is not limited thereto. In addition, the electron blocking layer EBL1 may be eliminated.

The active layer MQW1 may be disposed on the electron blocking layer EBL1. The active layer MQW1 may emit light as electron-hole pairs are combined therein in response to an electrical signal applied through the first semiconductor layer SEM11 and the second semiconductor layer SEM21. The active layer MQW1 may emit first light having a central wavelength range of 450 nm to 495 nm, i.e., light of the blue wavelength range.

The active layer MQW1 may include a material having a single or multiple quantum well structure. When the active layer MQW1 includes a material having the multiple quantum well structure, well layers and barrier layers may be alternately stacked on one another in the structure. The well layers may be made of InGaN, and the barrier layers may be made of GaN or AlGaN, but the present disclosure is not limited thereto. The thickness of the well layers may be approximately 1 nm to 4 nm, and the thickness of the barrier layers may be 3 nm to 10 nm.

Alternatively, the active layer MQW1 may have a structure in which a semiconductor material having a large band gap energy and a semiconductor material having a small band gap energy are alternately stacked on one another, and may include other Group III to Group V semiconductor materials depending on the wavelength range of the emitted light. The light emitted by the active layer MQW1 is not limited to the first light. In one or more embodiments, the second light (e.g., the light in the green wavelength range) or the third light (e.g., the light in the red wavelength range) may be emitted by the active layer MQW1. According to one or more embodiments of the present disclosure, when indium is included among the semiconductor materials included in the active layer MQW1, the color of emitted light may vary depending on the content of indium. For example, as the content of indium decreases, the wavelength range of output light may move to the red wavelength range, and as the content of indium decreases, the wavelength range of the output light may move to the blue wavelength range.

The superlattice layer SLT1 may be disposed on the active layer MQW1. The superlattice layer SLT1 may relieve stress between the second semiconductor layer SEM21 and the active layer MQW1. For example, the superlattice layer SLT1 may be made of InGaN and/or GaN. The thickness of the superlattice layer SLT1 may be approximately 50 to 200 nm. The superlattice layer SLT1 may be eliminated.

The second semiconductor layer SEM21 may be disposed on the superlattice layer SLT1. The second semiconductor layer SEM21 may be an n-type semiconductor. The second semiconductor layer SEM21 may include a semiconductor material having the following chemical formula: AlₓGa_{y}In_{1-x-y}N (0≤x≤1, 0≤y≤1 and 0≤x+y≤1). For example, it may be at least one of n-type doped AlGaInN, GaN, AlGaN, InGaN, AlN, and/or InN. The second semiconductor layer SEM21 may be doped with an n-type dopant, and the n-type dopant may be Si, Ge, Sn, etc. For example, the second semiconductor layer SEM21 may be n-GaN doped with n-type Si. The thickness of the second semiconductor layer SEM21 may range, but is not limited to, from 2 μm to 4 μm.

The bonding layer BL is disposed between the first light-emitting element stack S1 and the second light-emitting element stack S2. The bonding layer BL is formed of a material that is transparent and allows oxidation bonding, for example, indium tin oxide (ITO) and/or indium zinc oxide (IZO).

The first semiconductor layer SEM12 of the second light-emitting element stack S2 may be disposed on the bonding layer BL. The first semiconductor layer SEM12 may be p-type semiconductor, and may include a semiconductor material having the following chemical formula: AlₓGa_{y}In_{1-x-y}N (0≤x≤1, 0≤y≤1 and 0≤x+y≤1). For example, it may be at least one of p-type doped AlGaInN, GaN, AlGaN, InGaN, AlN, and/or InN. The first semiconductor layer SEM12 may be doped with a p-type dopant, and the p-type dopant may be Mg, Zn, Ca, Se, Ba, etc. For example, the first semiconductor layer SEM12 may be p-GaN doped with p-type Mg. The thickness of the first semiconductor layer SEM12 may range, but is not limited to, from 30 nm to 200 nm.

The electron blocking layer EBL2 of the second light-emitting element stack S2 may be disposed on the first semiconductor layer SEM12. The electron blocking layer EBL2 may suppress or prevent too many electrons from flowing into the active layer MQW2 of the second light-emitting element stack S2. For example, the electron blocking layer EBL2 may be p-AlGaN doped with p-type Mg. The thickness of the electron blocking layer EBL2 may be in a range of 10 nm to 50 nm, but the present disclosure is not limited thereto. In addition, the electron blocking layer EBL2 may be eliminated.

The active layer MQW2 of the second light-emitting element stack S2 may be disposed on the electron blocking layer EBL2. The active layer MQW2 may emit light as electron-hole pairs are combined therein in response to an electrical signal applied through the first semiconductor layer SEM12 and the second semiconductor layer SEM22. The active layer MQW1 may emit first light having a central wavelength range of 450 nm to 495 nm, i.e., light of the blue wavelength range.

The active layer MQW2 may include a material having a single or multiple quantum well structure. When the active layer MQW2 includes a material having the multiple quantum well structure, well layers and barrier layers may be alternately stacked on one another in the structure. The well layers may be made of InGaN, and the barrier layers may be made of GaN or AlGaN, but the present disclosure is not limited thereto. The thickness of the well layers may be approximately 1 nm to 4 nm, and the thickness of the barrier layers may be 3 nm to 10 nm.

Alternatively, the active layer MQW2 of the second light-emitting element stack S2 may have a structure in which a semiconductor material having a large band gap energy and a semiconductor material having a small band gap energy are alternately stacked on one another, and may include other Group III to Group V semiconductor materials depending on the wavelength range of the emitted light. The light emitted by the active layer MQW2 is not limited to the first light. In one or more embodiments, the second light (e.g., the light in the green wavelength range) or the third light (e.g., the light in the red wavelength range) may be emitted by the active layer MQW2. According to one or more embodiments of the present disclosure, when indium is included among the semiconductor materials included in the active layer MQW2, the color of the emitted light may vary depending on the content of indium. For example, as the content of indium decreases, the wavelength range of output light may move to the red wavelength range, and as the content of indium decreases, the wavelength range of the output light may move to the blue wavelength range.

The superlattice layer SLT2 of the second light-emitting element stack S2 may be disposed on the active layer MQW2. The superlattice layer SLT2 may relieve stress between the second semiconductor layer SEM22 and the active layer MQW2 of the second light-emitting element stack S2. For example, the superlattice layer SLT2 may be made of InGaN and/or GaN. The thickness of the superlattice layer SLT2 may be approximately 50 to 200 nm. The superlattice layer SLT2 may be eliminated.

The second semiconductor layer SEM22 of the second light-emitting element stack S2 may be disposed on the superlattice layer SLT2. The second semiconductor layer SEM22 may be an n-type semiconductor. The second semiconductor layer SEM22 may include a semiconductor material having the following chemical formula: AlₓGa_{y}In_{1-x-y}N (0≤x≤1, 0≤y≤1 and 0≤x+y≤1). For example, it may be at least one of n-type doped AlGaInN, GaN, AlGaN, InGaN, AlN, and/or InN. The second semiconductor layer SEM22 may be doped with an n-type dopant, and the n-type dopant may be Si, Ge, Sn, etc. For example, the second semiconductor layer SEM22 may be n-GaN doped with n-type Si. The thickness of the second semiconductor layer SEM22 may range, but is not limited to, from 2 μm to 4 μm.

The third semiconductor layer SEM32 of the second light-emitting element stack S2 may be disposed on the second semiconductor layer SEM22. The third semiconductor layer SEM32 may be disposed between the second semiconductor layer SEM22 and the common electrode CE. The third semiconductor layer SEM32 may be an undoped semiconductor. The third semiconductor layer SEM32 may include the same material as the second semiconductor layer SEM22, but may not be doped with an n-type or p-type dopant. In one or more embodiments, the third semiconductor layer SEM32 may be, but is not limited to, at least one of undoped InAlGaN, GaN, AlGaN, InGaN, AlN, and/or InN.

In one or more embodiments, a planarization layer PLL may be disposed on a plurality of pixel electrodes PE1, PE2, and PE3, and the insulating layer 130. The planarization layer PLL may provide a flat surface so that a common electrode CE, which will be described later, may be formed. The planarization layer PLL may be formed to have a suitable height (e.g., a predetermined height) so that at least a part, for example, an upper portion of the plurality of light-emitting elements LE, may protrude above the planarization layer PLL. That is to say, the height of the planarization layer PLL from the upper surface of the first pixel electrode PE1 may be less than the height of the light-emitting elements LE.

The planarization layer PLL may include an organic material to provide a flat surface. For example, the planarization layer PLL may include polyacrylate resin, epoxy resin, phenolic resin, polyamide resin, polyimide resin, unsaturated polyesters resin, poly phenylen ether resin, poly phenylene sulfide resin, benzocyclobutene (BCB), etc.

The common electrode CE may be disposed on the planarization layer PLL and the plurality of light-emitting elements LE. Specifically, the common electrode CE may be disposed on one surface of the first substrate 110 on which the light-emitting element LE is formed, and may be disposed entirely on the display area DPA and the non-display area NDA. The common electrode CE may be disposed to overlap the emission areas EA1, EA2, and EA3 in the display area DPA, and may have a small thickness to allow light to exit.

The common electrode CE may be disposed directly on upper and side surfaces of the plurality of light-emitting elements LE. The common electrode CE may be in direct contact with the second semiconductor layer SEM22 and the third semiconductor layer SEM32 of the second light-emitting element stack S2 from among side surfaces of the light-emitting elements LE. As shown in FIG. 5, the common electrode CE may be a common layer that covers the plurality of light-emitting elements LE and commonly connects the plurality of light-emitting elements LE with one another. Because the conductive second semiconductor layer SEM22 has a patterned structure in each of the light-emitting elements LE, the common electrode CE may be in direct contact with the side surfaces of the second semiconductor layer SEM22 and the third semiconductor layer SEM32 of the second light-emitting element stack S2 of each of the light-emitting elements LE so that a common voltage can be applied to each of the light-emitting elements LE.

Because the common electrode CE is disposed entirely on the first substrate 110 to apply the common voltage, the common electrode CE may include a material having a low resistance. In addition, the common electrode CE may be formed to have a small thickness to allow light to exit. For example, the common electrode CE may include a material having a low resistance, such as aluminum (Al), silver (Ag), and/or copper (Cu). The thickness of the common electrode CE may be, but is not limited to, approximately 10 Å to 200 Å.

The above-described light-emitting elements LE may receive a pixel voltage or an anode voltage from the pixel electrodes PE1, PE2, and PE3, and may receive the common voltage through the common electrode CE. The light-emitting elements LE may emit light with a luminance (e.g., a predetermined luminance) according to a voltage difference between the pixel voltage and the common voltage.

According to the current embodiment, by disposing a plurality of light-emitting elements LE, i.e., inorganic light-emitting diodes on the pixel electrodes PE1, PE2, and PE3, it is possible to make the organic light-emitting diodes less vulnerable to external moisture or oxygen, and improve the lifetime and the reliability of the organic light-emitting diodes.

As shown in FIG. 7, the bonding layer BL may be eliminated according to one or more embodiments. When the bonding layer BL is eliminated, the second light-emitting element stack S2 may be stacked directly on the first light-emitting element stack S1.

The first light-emitting element stack S1 may include a first semiconductor layer SEM11, an electron blocking layer EBL1, an active layer MQW1, a superlattice layer SLT1, and a second semiconductor layer SEM21. The first semiconductor layer SEM11, the electron blocking layer EBL1, the active layer MQW1, the superlattice layer SLT1, and the second semiconductor layer SEM21 may be stacked on one another in this order in the third direction DR3.

The second light-emitting element stack S2 may include a first semiconductor layer SEM12, an electron blocking layer EBL2, an active layer MQW2, a superlattice layer SLT2, a second semiconductor layer SEM22, and a third semiconductor layer SEM32. The first semiconductor layer SEM12, the electron blocking layer EBL2, the active layer MQW2, the superlattice layer SLT2, the second semiconductor layer SEM22, and the third semiconductor layer SEM32 may be stacked on one another in this order in the third direction DR3.

The second semiconductor layer SEM21 of the first light-emitting element stack S1 may be in direct contact with the first semiconductor layer SEM12 of the second light-emitting element stack S2.

The first semiconductor layer SEM12 may be disposed on the second semiconductor layer SEM21 of the first light-emitting element stack S1. The semiconductor layers have been described above with reference to FIG. 6; and, therefore, the redundant descriptions will be omitted.

The voltages in a display device may be roughly divided into driving voltage and light-emitting element voltage. The driving voltage is used for the driving circuits, and the light-emitting element voltage is used for the light-emitting elements. Because the driving voltage is constant regardless of the structure of the light-emitting elements, the light-emitting elements of the tandem structure exhibits twice the luminance of existing light-emitting elements for the same current, but the voltage does not double. For example, an existing light-emitting element without a tandem structure may require the light-emitting element voltage of approximately 3V and the driving circuit voltage of approximately 6V. In contrast, a light-emitting element having the tandem structure according to one or more embodiments of the present disclosure may require the light-emitting element voltage of 6V. Therefore, the existing light-emitting element requires the total voltage of 9 V, i.e., the light-emitting element voltage of 3V plus the driving circuit voltage of 6V, whereas the light-emitting element having the tandem structure according to one or more embodiments requires the total voltage of 12 V, i.e., the light-emitting element voltage of 6V plus the driving circuit voltage of 6V. As the display device including the light-emitting elements having the tandem structure provides twice the luminance for the same current, and thus it can be seen that the efficiency is improved by about 45% compared to a display device including the existing light-emitting elements.

In this way, the display device employing the light-emitting elements of the tandem structure can be driven with lower power consumption.

Referring back to FIG. 5, the wavelength-converting portion 200 may be disposed on the light-emitting element portion LEP. The wavelength-converting portion 200 may include partition walls PW, wavelength conversion layers QDL, color filters CF1, CF2, and CF3, a light-blocking member BK, and a protective layer PTL.

The partition walls PW may be disposed on the common electrode CE in the display area DPA, and may partition the plurality of emission areas EA1, EA2, and EA2. The partition walls PW may be extended in the first direction DR1 and the second direction DR2, and may be formed in a lattice pattern throughout the display area DPA. In addition, the partition walls PW may not overlap the plurality of emission areas EA1, EA2, and EA3, and may overlap the non-emission area NEA.

The partition walls PW may include a plurality of openings OP1, OP2, and OP3 exposing the common electrode CE thereunder. The plurality of openings OP1, OP2, and OP3 may include a first opening OP1 overlapping the first emission area EA1, a second opening OP2 overlapping the second emission area EA2, and a third opening OP3 overlapping the third emission area EA3. The plurality of openings OP1, OP2, and OP3 may be in line with the plurality of emission areas EA1, EA2, and EA3, respectively. In other words, the first opening OP1 may be in line with the first emission area EA1, the second opening OP2 may be in line with the second emission area EA2, and the third opening OP3 may be in line with the third emission area EA3.

The partition walls PW may provide a space where the wavelength conversion layers QDL can be formed. To this end, the partition walls PW may have a suitable thickness (e.g., a predetermined thickness), for example, the thickness of the partition wall PW may be in the range of 1 μm to 10 μm. The partition walls PW may include an organic insulating material to have a suitable thickness (e.g., a predetermined thickness). The organic insulating material may include, for example, an epoxy-based resin, an acrylic-based resin, a cardo-based resin, an imide-based resin, etc.

The wavelength conversion layers QDL may be disposed on the plurality of openings OP1, OP2, and OP3, respectively. The wavelength conversion layers QDL may convert or shift the peak wavelength of the incident light into light of another peak wavelength. The wavelength conversion layers QDL may convert some of the blue first lights emitted from the light-emitting elements LE into a yellow fourth light. In the wavelength conversion layers QDL, the first light and the fourth light may be mixed to emit a white fifth light. The fifth light may be converted into the first light through the first color filter CF1, may be converted into the second light through the second color filter CF2, and may be converted into the third light through the third color filter CF3.

The wavelength conversion layers QDL may be disposed in the plurality of openings OP1, OP2, and OP3, respectively, and may be spaced from one another. That is to say, the wavelength conversion layers QDL may be formed in a pattern of dot-shaped islands that are spaced from one another. For example, the wavelength conversion layers QDL may be disposed in the first opening OP1, the second opening OP2, and the third opening OP3, respectively, and the number of the wavelength conversion layers QDL may be equal to the number of the openings. In addition, the wavelength conversion layer QDL may be disposed to overlap each of the first emission area EA1, the second emission area EA2, and the third emission area EA3. According to one or more embodiments of the present disclosure, the wavelength conversion layers QDL may completely overlap the first emission area EA1, the second emission area EA2, and the third emission area EA3.

The wavelength conversion layer QDL may include a first base resin BRS1 and first wavelength-converting particles WCP1. The first base resin BRS1 may include a light-transmitting organic material. For example, the first base resin BRS1 may include an epoxy-based resin, an acrylic-based resin, a cardo-based resin, an imide-based resin, etc.

The first wavelength-converting particles WCP1 may convert the first light incident from the light-emitting element LE into the fourth light. For example, the first wavelength-converting particles WCP1 may convert light in the blue wavelength range into light in the yellow wavelength range. The first wavelength-converting particles WCP1 may be quantum dots (QD), quantum rods, fluorescent material, and/or phosphorescent material. For example, quantum dots may be particulate matter that emits a color as electrons transition from the conduction band to the valence band.

The quantum dots may be semiconductor nanocrystalline material. The quantum dots have a specific band gap depending on their compositions and size, and can absorb light and emit light having an intrinsic wavelength. Examples of the semiconductor nanocrystals of the quantum dots may include Group IV nanocrystals, Groups II-VI compound nanocrystals, Groups III-V compound nanocrystals, Groups IV-VI nanocrystals, or combinations thereof.

The Group II-VI compounds may be selected from the group consisting of: binary compounds selected from the group consisting of CdSe, CdTe, ZnS, ZnSe, ZnTe, ZnO, HgS, HgSe, HgTe, MgSe, MgS, and a mixture thereof; ternary compounds selected from the group consisting of InZnP, AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; and quaternary compounds selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof.

The Group III-V compounds may be selected from the Group consisting of: binary compounds selected from the group consisting of GaN, GaP, GaAs, GaSb, AlN, AlP, AlAs, AlSb, InN, InP, InAs, InSb, and a mixture thereof; ternary compounds selected from the group consisting of GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, GaAlNP, and a mixture thereof; and quaternary compounds selected from the group consisting of GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof.

The Group IV-VI compounds may be selected from the group consisting of: binary compounds selected from the group consisting of SnS, SnSe, SnTe, PbS, PbSe, PbTe, and a mixture thereof; ternary compounds selected from the group consisting of SnSeS, SnSeTe, SnSTe, PbSeS, PbSeTe, PbSTe, SnPbS, SnPbSe, SnPbTe, and a mixture thereof; and quaternary compounds selected from the group consisting of SnPbSSe, SnPbSeTe, SnPbSTe, and a mixture thereof. The Group IV elements may be selected from the group consisting of Si, Ge, and a mixture thereof. The Group IV compounds may be binary compounds selected from the group consisting of SiC, SiGe, and a mixture thereof.

The binary compounds, the ternary compounds, or the quaternary compounds may be present in the particles at a uniform concentration, or may be present in the same particles at partially different concentrations. In addition, they may have a core/shell structure in which one quantum dot surrounds another quantum dot. At the interface between the core and the shell, the gradient of the concentrate of atoms in the shell may decrease toward the center.

According to one or more embodiments of the present disclosure, the quantum dots may have a core-shell structure including a core comprising the nanocrystals and a shell surrounding the core. The shell of the quantum-dots may serve as a protective layer for maintaining the semiconductor properties by preventing chemical denaturation of the core and/or as a charging layer for imparting electrophoretic properties to the quantum dots. The shell may be either a single layer or multiple layers. Examples of the shell of the quantum dot may include an oxide of a metal or a non-metal, a semiconductor compound, a combination thereof, etc.

For example, examples of the metal or non-metal oxide may include, but is not limited to, binary compounds such as SiO₂, Al₂O₃, TiO₂, ZnO, MnO, Mn₂O₃, Mn₃O₄, CuO, FeO, Fe₂O₃, Fe₃O₄, CoO, Co₃O₄ and NiO or ternary compounds such as MgAl₂O₄, CoFe₂O₄, NiFe₂O₄, and/or CoMn₂O₄.

In addition, examples of the semiconductor compound may include, but is not limited to, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc.

The wavelength conversion layer QDL may further include scatterers for scattering the light of the light-emitting element LE in random directions. The scatterers may have a refractive index different from that of the first base resin BRS1 and may form an optical interface with the first base resin BRS1. For example, the scatterers may be light-scattering particles. The material of the scatterers is not particularly limited as long as they can scatter at least some of the transmitted lights. For example, the scatterers may be metal oxide particles or organic particles. Examples of the metal oxide may include titanium oxide (TiO₂), zirconium oxide (ZrO₂), aluminum oxide (Al₂O₃), indium oxide (In₂O₃), zinc oxide (ZnO), tin oxide (SnO₂), etc. Examples of the material of the organic particles may include an acrylic resin, a urethane resin, etc. The scatterers can scatter light in random directions regardless of the incident direction of the incident lights without substantially converting the wavelengths of the lights.

As the thickness of the wavelength conversion layers QDL increases in the third direction DR3, the content of the first wavelength-converting particles WCP1 contained in the wavelength conversion layers QDL increases, so that light conversion efficiency of the wavelength conversion layers QDL can be increased. Therefore, it is desired that the thickness of the wavelength conversion layers QDL is determined based on the light conversion efficiency of the wavelength conversion layers QDL.

In the above-described wavelength-converting portion 200, some of the first lights emitted from the light-emitting elements LE may be converted into the fourth light in the wavelength conversion layers QDL. In the wavelength conversion layers QDL, the first light and the fourth light may be mixed to emit the white fifth light. When the fifth light is emitted from the wavelength conversion layers QDL, only the first light may be transmitted through the first color filter CF1, only the second light may be transmitted through the second color filter CF2, and only the third light may be transmitted through the third color filter CF3. Accordingly, the light emitted from the wavelength-converting portion 200 may be blue, red, and green light of the first light, the second light, and the third light, thereby achieving a full color.

The plurality of color filters CF1, CF2, and CF3 may be disposed on the partition walls PW and the wavelength conversion layers QDL. The plurality of color filters CF1, CF2, and CF3 may be disposed to overlap the plurality of openings OP1, OP2, and OP3 and the wavelength conversion layers QDL. The plurality of color filters CF1, CF2, and CF3 may include the first color filter CF1, the second color filter CF2, and the third color filter CF3.

The first color filter CF1 may be in line with the first emission area EA1 and partially overlap with the non-emitting area NEA. In addition, the first color filter CF1 may be disposed on the first opening OP1 of the partition walls PW to overlap with the first opening OP1 and may partially overlap with the light-blocking member BK on the partition walls PW. The first color filter CF1 may transmit the first light emitted from the light-emitting element LE and may absorb or block the second light and the third light. For example, the first color filter CF1 may transmit light in the blue wavelength range and may absorb or block light in the green and red wavelength ranges.

The second color filter CF2 may be in line with the second emission area EA2 and partially overlap with the non-emitting area NEA. In addition, the second color filter CF2 may be disposed on the second opening OP2 of the partition walls PW to overlap with the second opening OP2 and may partially overlap with the light-blocking member BK. The second color filter CF2 may transmit the second light and may absorb or block the first light and the third light. For example, the second color filter CF2 may transmit light in the green wavelength range and may absorb or block light in the blue and red wavelength ranges.

The third color filter CF3 may be in line with the third emission area EA3 and partially overlap with the non-emitting area NEA. In addition, the third color filter CF3 may be disposed on the third opening OP3 of the partition walls PW to overlap with the third opening OP3 and may partially overlap with the light-blocking member BK. The third color filter CF3 may transmit the third light and may absorb or block the first light and the second light. For example, the third color filter CF3 may transmit light in the red wavelength range and may absorb or block light in the blue and green wavelength ranges.

The light-blocking member BM may be disposed on the partition walls PW. The light-blocking member BK may overlap the non-emission area NEA to block transmission of light. The light-blocking member BK may be disposed in a substantially lattice shape when viewed from the top, similar to the partition walls PW. The light-blocking member BK may overlap with the partition walls PW but not with the emission areas EA1, EA2, and EA3.

According to one or more embodiments, the light-blocking member BK may include an organic light-blocking material and may be formed via processes of coating the organic light-blocking material and exposing it to light. The light-blocking member BK may include a dye or pigment having light-blocking properties, and may be a black matrix. At least a part of the light-blocking member BK may overlap adjacent color filters CF1, CF2, and CF3 in the third direction DR3, and the color filters CF1, CF2 and CF3 may be disposed on at least a part of the light-blocking member BK.

External light incident from the outside of the display device 10 may result in a problem that the color gamut of the wavelength-converting portion 200 is distorted. According to the present embodiment where the light-blocking member BK is disposed on the wavelength-converting portion 200, at least a part of external light is absorbed by the light-blocking member BK. By doing so, it is possible to reduce color distortion due to the reflection of the external light. In addition, the light-blocking member BK can prevent the color mixture occurring when light leaks between adjacent emission areas, thereby further improving the color gamut.

The protection layer PTL may be disposed on the plurality of color filters CF1, CF2, and CF3, and the light-blocking member BK. The first protection layer PTL may be disposed at the top of the display device 10 to protect the plurality of color filters CF1, CF2, and CF3 and the light-blocking member BK. One surface, for example, the lower surface of the protection layer PTL may be in contact with the plurality of color filters CF1, CF2, and CF3 and the upper surface of the light-blocking member BK.

The protection layer PTL may include an inorganic insulating material to protect the plurality of color filters CF1, CF2, and CF3 and the light-blocking member BK. For example, the first protection layer PTL may include, but is not limited to, silicon oxide (SiOx), silicon nitride (SiNx), silicon oxynitride (SiOxNy), aluminum oxide (AlxOy), aluminum nitride (AlN), etc. The protection layer PTL may have a suitable thickness (e.g., a predetermined thickness), for example, in a range of 0.01 to 1 μm. It is, however, to be understood that the present disclosure is not limited thereto.

In the display device 10 according to one or more embodiments, the light-emitting elements LE may be disposed on a protruding portion of one of the pixel electrodes PE1, PE2, and PE3, so that it is possible to prevent incomplete adhesion of the light-emitting elements LE over different levels.

Although the light-emitting element LE includes the two layers, i.e., the light-emitting element stacks S1 and S2 in the display device 10 described above with reference to FIGS. 5 to 7, the present disclosure is not limited thereto. The light-emitting element LE may include two or more light-emitting element stacks. When the display device 10 includes light-emitting elements LE in which two or more light-emitting element stacks are stacked, each of the light-emitting element stacks includes a first semiconductor layer, an electron blocking layer, an active layer, a superlattice layer, and a second semiconductor layer, and the top light-emitting element stack may further include a third semiconductor layer. The third semiconductor layer of the top light-emitting element stack may be in contact with the common electrode.

The light-emitting element LE in which two or more light-emitting element stacks are stacked may further include a bonding layer BL between the light-emitting element stacks, like the light-emitting element shown in FIG. 6. The bonding layer BL is made of indium tin oxide (ITO) and/or indium zinc oxide (IZO).

In one or more embodiments, the light-emitting element stacks S1 and S2 may be in direct contact with each other, like the light-emitting element shown in FIG. 7. In this instance, the second semiconductor layer SEM21 of the light-emitting element stack S1 at the bottom may be in contact with the first semiconductor layer SEM12 of the light-emitting element stack S2 at the top.

As described above with reference to FIGS. 5 to 7, as the light-emitting element is formed in the tandem structure, even if a short circuit is created in one of the light-emitting element stacks, the light-emitting element can still emit light, and thus no repair is required.

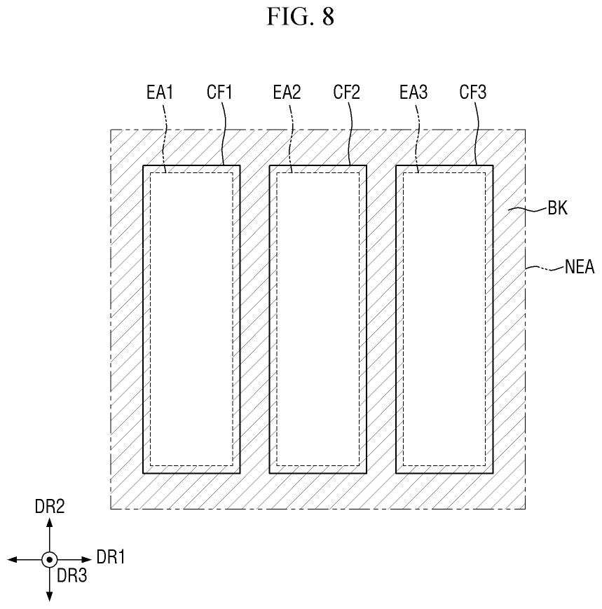

FIG. 8 is a plan view schematically showing a plurality of emission areas and a plurality of color filters.

As shown in FIG. 8, the area of the plurality of color filters CF1, CF2, and CF3 may be greater than the area of the plurality of emission areas EA1, EA2, and EA3 when viewed from the top. For example, the first color filter CF1 may have a larger area than the first emission area EA1 when viewed from the top. The second color filter CF2 may have a larger area than the second emission area EA2 when viewed from the top. The third color filter CF3 may have a larger area than the third emission area EA3 when viewed from the top. It should be understood, however, that the present disclosure is not limited thereto. The area of the plurality of color filters CF1, CF2, and CF3 may be equal to the area of the plurality of emission areas EA1, EA2, and EA3 when viewed from the top.

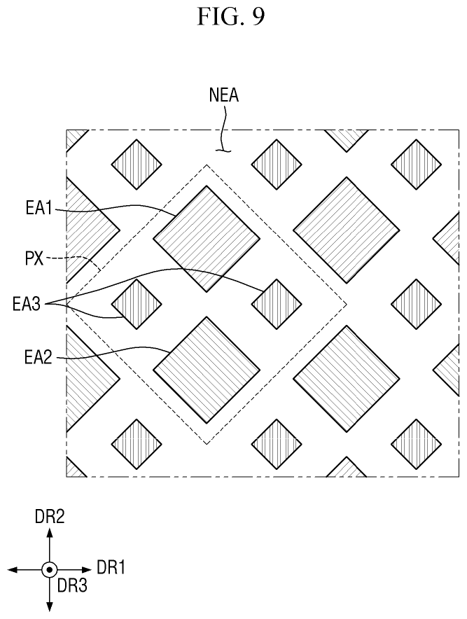

FIG. 9 is a plan view showing a modification of the emission areas of the display device according to one or more embodiments.

In the example shown in FIGS. 5 to 8, a pixel includes three pixel areas, i.e., a first emission area EA1 emitting light of a first color, a second emission area EA2 emitting light of a second color, and a third emission area EA3 emitting light of a third color light.

On the other hand, according to the embodiment of FIG. 9, a pixel may include two third emission areas EA3 emitting light of the third color, and accordingly a pixel may include four emission areas EA1, EA2, and two EA3.

In one or more embodiments, the emission areas EA1, EA2, and EA3 may be arranged in a PENTILE® structure, or the like. The PENTILE® pixel arrangement structure may be referred to as an RGBG matrix structure (e.g., a PENTILE® matrix structure or an RGBG structure (e.g., a PENTILE® structure)). PENTILE® is a registered trademark of Samsung Display Co., Ltd., Republic of Korea. As shown in FIG. 9, a plurality of first emission areas EA1 may be arranged in the first row in the first direction DR1, a plurality of second emission areas EA2 may be arranged in the second row in the first direction, and the first row and the second row may be alternately arranged in the second direction DR2.

According to one or more embodiments, the size of the first emission area EA1, the size of the second emission area EA2 and the size of the third emission area EA3 may be substantially all equal. It should be understood, however, that the present disclosure is not limited thereto. For example, as shown in FIG. 9, the size of the first emission area EA1 may be equal to the size of the second emission area EA2, and the size of the third emission areas EA3 may be different from the first emission area EA1 and the second emission area EA2. In addition, the size of the first emission area EA1 may be larger than the size of the second emission area EA2, or the size of the first emission area EA1 may be smaller than the size of the second emission area EA2.

In addition, the distance between the first emission area EA1 and the second emission area EA2 adjacent to each other, the distance between the second emission area EA2 and the third emission area EA3 adjacent to each other, and the distance between the first emission area EA1 and the third emission area EA3 adjacent to each other may be substantially all equal, but the present disclosure is not limited thereto. For example, the distance between the first emission area EA1 and the second emission area EA2 adjacent to each other may be different from the distance between the second emission area EA2 and the third emission areas EA3 adjacent to each other. The distance between the first emission area EA1 and the third emission areas EA3 adjacent to each other may be different from the distance between the second emission area EA2 and the third emission areas EA3 adjacent to each other.

In addition, the first emission area EA1 may emit the first light, the second emission area EA2 may emit the second light, and the third emission area EA3 may emit the third light. It should be understood, however, that the present disclosure is not limited thereto. For example, the first emission area EA1 may emit the first light, the second emission area EA2 may emit the third light, and the third emission areas EA3 may emit the second light. Alternatively, the first emission area EA1 may emit the second light, the second emission area EA2 may emit the first light, and the third emission areas EA3 may emit the third light. Alternatively, the first emission area EA1 may emit the third light, the second emission area EA2 may emit the second light, and the third emission areas EA3 may emit the third light.

In addition, the first emission area EA1, the second emission area EA2 and the third emission areas EA3 may have, but is not limited to, a rectangular shape when viewed from the top. For example, the first emission area EA1, the second emission area EA2, and the third emission areas EA3 may have a polygonal shape such as a triangle, a pentagon, a hexagon, or an octagon, a circular shape, an elliptical shape, or irregular shapes.

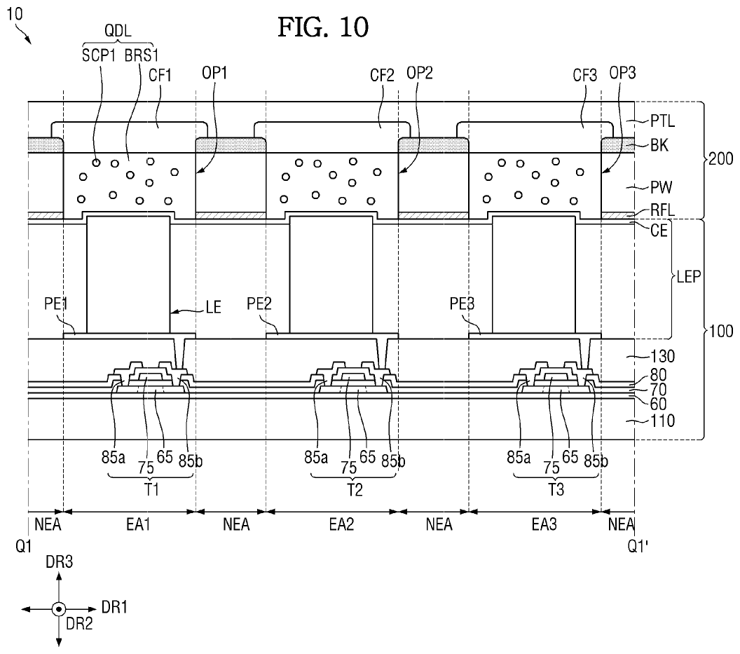

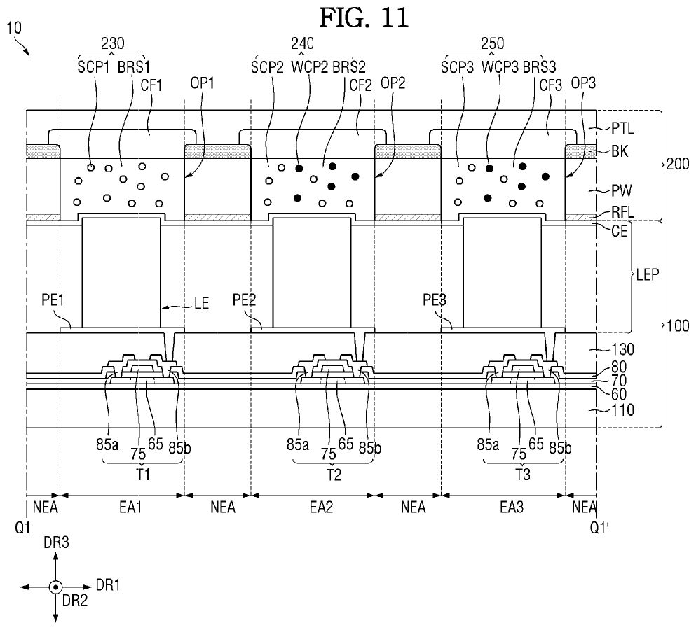

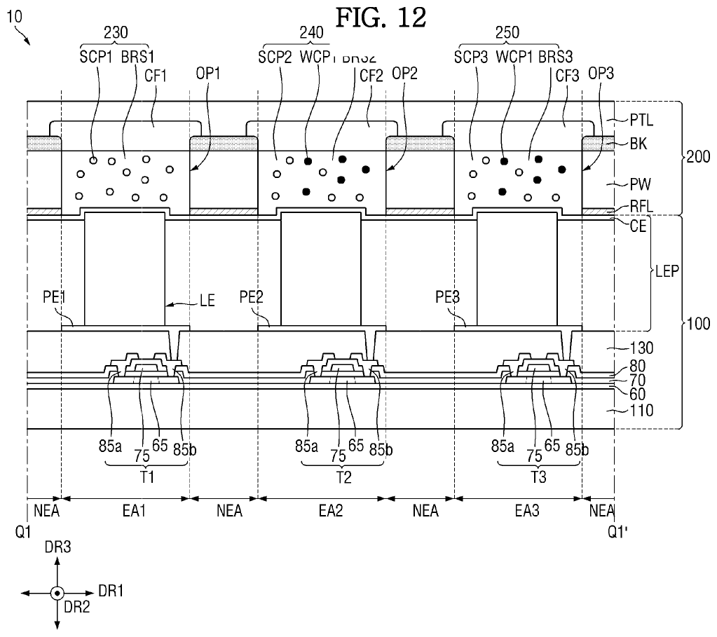

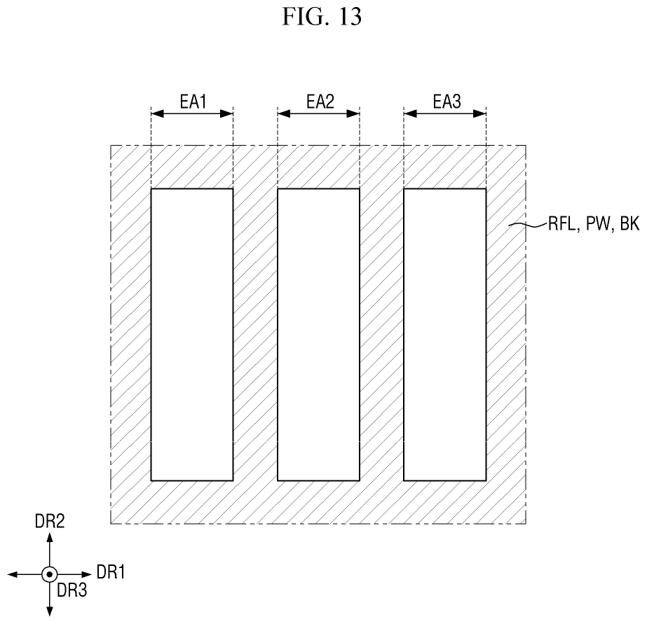

FIG. 10 is a cross-sectional view showing a display device according to one or more embodiments of the present disclosure. FIG. 11 is a cross-sectional view showing a display device according one or more embodiments. FIG. 12 is a cross-sectional view schematically showing a display device according to one or more embodiments. FIG. 13 is a plan view schematically showing a plurality of emission areas and a reflective metal layer.

The embodiment of FIGS. 10 to 13 is different from the above-described embodiments of FIGS. 6 to 9 in that a reflective metal layer RFL is further disposed between a common electrode CE and partition walls PW. In the following description, descriptions will focus on the difference from the above embodiments; and, therefore, the redundant descriptions will be omitted.

According to one or more embodiments, the reflective metal layer RFL may be disposed between the common electrode CE and the partition walls PW. The reflective metal layer RFL may not be in line with the emission areas EA1, EA2, and EA3 but may overlap with the non-emission area NEA. The reflective metal layer RFL may be extended in the first direction DR1 and the second direction DR2, and may be formed in a lattice pattern throughout the display area DPA. The reflective metal layer RFL may entirely overlap with the partition walls PW and may also overlap with the light-blocking member BK.

According to one or more embodiments of the present disclosure, the light-emitting element LE of the first emission area EA1 may emit blue first light, the light-emitting element LE of the second emission area EA2 may emit red second light, and the light-emitting element LE of the third emission area EA3 may emit green third light. The light-blocking member BK serves to prevent color mixing of lights between the emission areas EA1, EA2, and EA3.

The reflective metal layer RFL may be disposed in the non-emission area NEA overlapping with the light-blocking member BK to prevent color mixing of the lights from the emission areas EA1, EA2, and EA3.

Incidentally, in the example shown in FIG. 10, the light-emitting element LE of the first emission area EA1 may emit blue first light, the light-emitting element LE of the second emission area EA2 may emit red second light, and the light-emitting element LE of the third emission area EA3 may emit green third light. In this instance, the wavelength conversion layer QDL includes first scattering particles SCP1 and a first base resin BRS1 to scatter lights emitted from the light-emitting elements LE so that the lights exit through the color filters CF1, CF2, and CF3.

Referring to FIG. 11, according to one or more embodiments, the light-emitting elements LE disposed in the first emission area EA1, the second emission area EA2, and the third emission area EA3 may emit the blue first light. In this instance, the wavelength conversion layer QDL may include a light-transmitting pattern 230 overlapping with the first emission area EA1, a first wavelength-converting pattern 240 overlapping with the second emission area EA2, and a second wavelength-converting pattern 250 overlapping with third emission area EA3.

The light-transmitting pattern 230 may be disposed in the first opening OP1 and may be in line with the first emission area EA1 and the first color filter CF1. The light-transmitting pattern 230 can transmit incident light. The first light emitted from the light-emitting elements LE disposed in the first emission area EA1 may be blue light. The first light, which is blue light, may pass through the light-transmitting pattern 230 and exit to the first emission area EA1. The light-transmitting pattern 230 may include the first base resin BRS1 and the first scattering particles SCP1 dispersed in the first base resin BRS1. The first base resin BRS1 and the scattering particles have been described above; and, therefore, the redundant descriptions will be omitted.

The first wavelength-converting pattern 240 may be disposed in the second opening OP2 and may be in line with the second emission area EA2 and the second color filter CF2. The first wavelength-converting pattern 240 may convert or shift the peak wavelength of the incident light into light of another peak wavelength and emit the light. According to one or more embodiments, the first wavelength-converting pattern 240 converts the first light emitted from the light-emitting element LE of the second emission area EA2 into the second light, i.e., the red light, which has a single peak wavelength in the range of approximately 610 nm to 650 nm, to output the light.

The first wavelength-converting pattern 240 may include a second base resin BRS2, and second wavelength-converting particles WCP2, and second scattering particles SCP2 dispersed in the second base resin BRS2.

The second base resin BRS2 may be made of a material having high light transmittance and may be made of the same material as the first base resin BRS1 described above.

The second wavelength-converting particles WCP2 may convert or shift the peak wavelength of the incident light to another peak wavelength. According to one or more embodiments, the second wavelength-converting particles WCP2 may convert the light of the first color, which is blue light provided from the light-emitting element LE, into third light, which is red light having a single peak wavelength in the range of approximately 610 to 650 nm, to output it. Examples of the second wavelength-converting particles WCP2 may include quantum dots, quantum rods, phosphors, etc. The second wavelength-converting particles WCP2 are substantially identical to the first wavelength-converting particles WCP1 described above; and, therefore, the redundant description will be omitted.

Some of the first light, which is blue light emitted from the light-emitting element LE may not be converted into second light, which is red light, by the second wavelength-converting particles WCP2 but may pass through the first wavelength-converting pattern 240. However, light that is not converted to red light may be blocked by the second color filter CF2. On the other hand, red light that is a part of the first light emitted from the light-emitting element LE and converted by the first wavelength-converting pattern 240 passes through the second color filter CF2 to exit to the outside.

The second wavelength-converting pattern 250 may be disposed in the third opening OP3 and may be in line with the third emission area EA3 and the third color filter CF3. The second wavelength-converting pattern 250 may convert or shift the peak wavelength of the incident light into light of another peak wavelength and emit the light. According to one or more embodiments, the second wavelength conversion pattern 250 converts the first light emitted from the light-emitting element LE of the third emission area EA3 into the third light, i.e., the green light, which has a single peak wavelength in the range of approximately 510 nm to 550 nm, to output the light.

The second wavelength-converting pattern 250 may include a third base resin BRS3, and third wavelength-converting particles WCP3 and third scattering particles SCP3 dispersed in the third base resin BRS3.

The third base resin BRS3 may be made of a material having high light transmittance, and may be made of the same material as the first base resin BRS1, the second base resin BRS2, and the third base resin BRS3, or may include at least one of the above-listed materials as the constituent material.

The third wavelength-converting particles WCP3 may convert or shift the peak wavelength of the incident light to another peak wavelength. According to one or more embodiments, the third wavelength-converting particles WCP3 may convert the light of the first color, which is blue light provided from the light-emitting element LE, into third light, which is green light having a peak wavelength in the range of approximately 510 to 550 nm, to output it.

Examples of the third wavelength-converting particles WCP3 may include quantum dots, quantum rods, phosphors, etc. The third wavelength-converting particles WCP3 are substantially identical to the first wavelength-converting particles WCP1 described above; and, therefore, the redundant description will be omitted.

A part of the first light, which is blue light emitted from the light-emitting element LE may not be converted into third light, which is green light, by the third wavelength-converting particles WCP3. However, the first light that is not converted into green light may be blocked by the third color filter CF3 disposed thereon. On the other hand, the green light converted by the second wavelength-converting pattern 250 passes through the third color filter CF3 and exit to the outside.

The display device 10 according to the above-described embodiment forms the wavelength conversion layer QDL including the light-transmitting pattern 230, the first wavelength-converting pattern 240, and the second wavelength-converting pattern 250, so that it is possible to improve the efficiency of outputting blue, green, and red lights.

The embodiment of FIG. 12 is different from the exemplary embodiment of FIG. 11 in that each of the first wavelength-converting pattern 240 and the second wavelength-converting pattern 250 includes first wavelength-converting particles WCP1.

Each of the first wavelength conversion pattern 240 and the second wavelength-converting pattern 250 may include first wavelength-converting particles WCP1 that convert the first blue light into yellow fourth light. Accordingly, the blue first light emitted from the light-emitting elements LE disposed in the second emission area EA2 and the third emission area EA3 may be converted into the yellow fourth light. In each of the first wavelength conversion pattern 240 and the second wavelength-converting pattern 250, the blue first light and the yellow fourth light are mixed so that white fifth light exits. The fifth light may be converted into the second light in the second color filter CF2 and into the third light in the third color filter CF3, so that the second light for the third light may exit.

Hereinafter, processing steps of fabricating the display device 10 will be described with reference to other drawings.

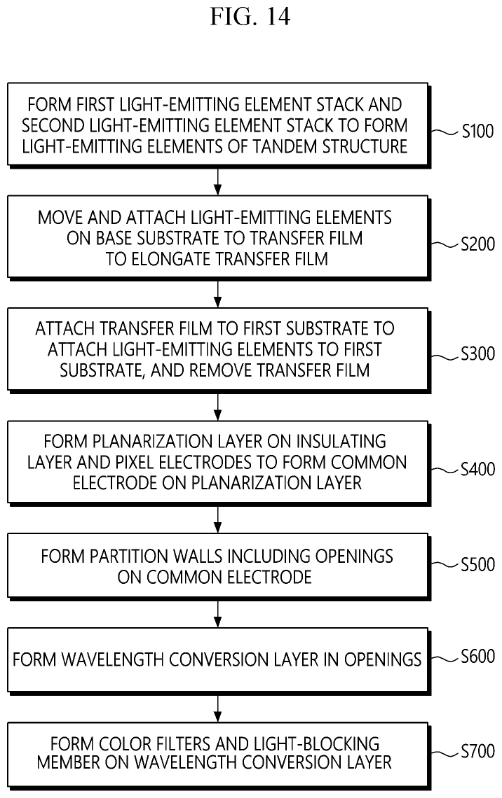

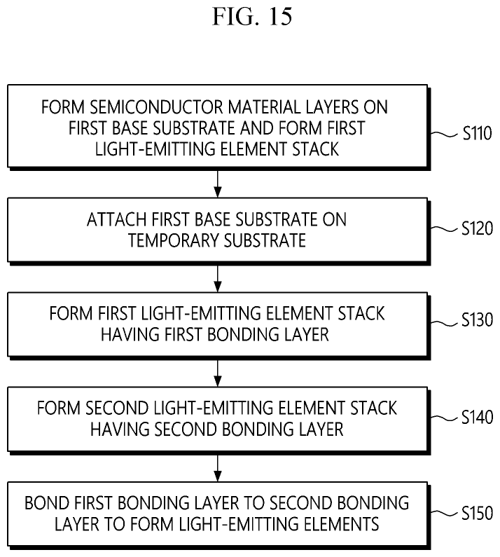

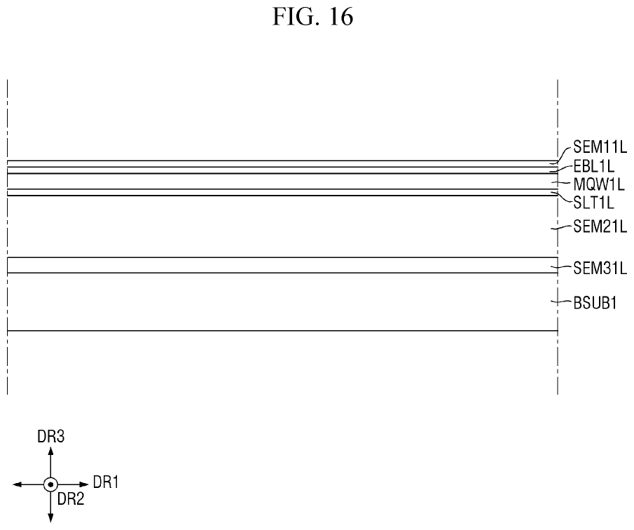

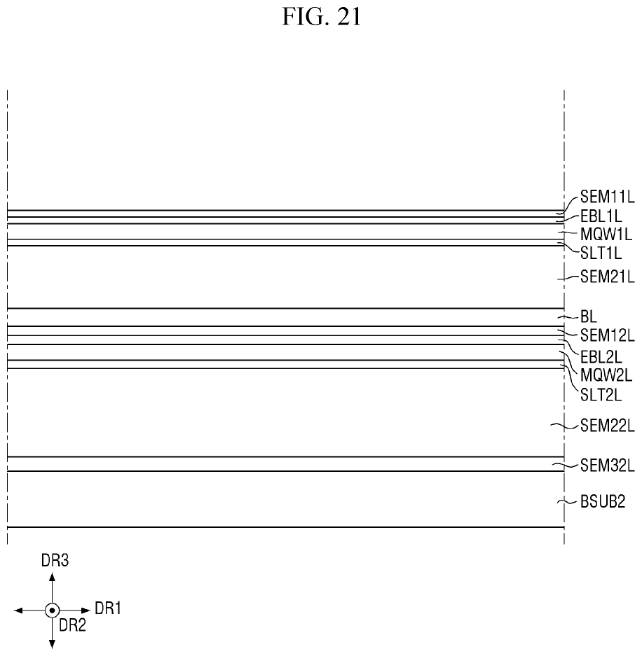

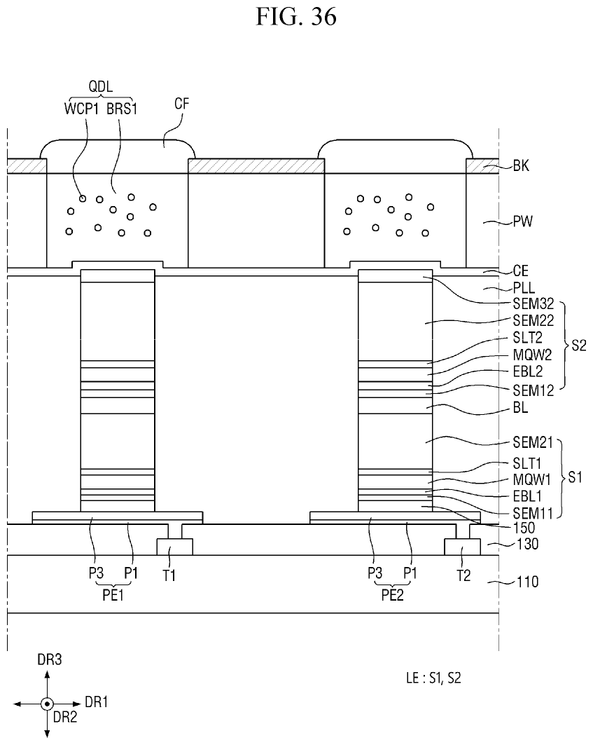

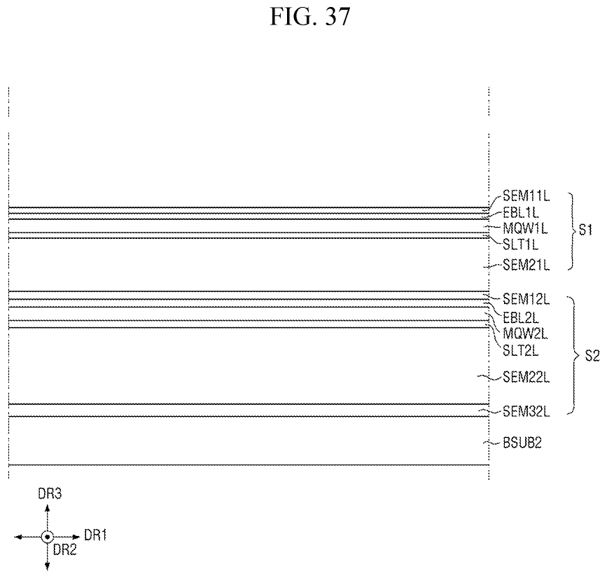

FIG. 14 is a flowchart for illustrating a method of fabricating a display device according to one or more embodiments of the present disclosure. FIG. 15 is a flowchart for illustrating in more detail step S100 of FIG. 14 according to one or more embodiments. FIGS. 16 to 36 are views for illustrating the method of fabricating the display device according to one or more embodiments. FIG. 37 is a view for illustrating step S100 of FIG. 14 according to one or more embodiments.

FIGS. 16 to 36 are cross-sectional views and plan views showing structures of layers of the display device 10 according to the order in which they are formed. FIGS. 16 to 36 mainly show a process of fabricating the light-emitting element portion LEP and the wavelength-converting portion 200, which may generally correspond to the cross-sectional view of FIG. 5. In the following description, the first emission area EA1 and the second emission area EA2 of the display device 10 will be mainly illustrated. Hereinafter, a method of fabricating the display device shown in FIGS. 16 to 36 will be described in conjunction with FIGS. 14 and 15.

Referring to FIGS. 16 to 23, a first light-emitting element stack and a second light-emitting element stack are formed so that a plurality of light-emitting elements LE having a tandem structure is formed (step S100 of FIG. 14).

More specifically, referring to FIG. 16, a plurality of semiconductor material layers SEM31L, SEM21L, SLT1L, MQW1L, EBL1L, and SEM11L is formed on a first base substrate BSUB1 (step S110 of FIG. 15).

Initially, the first base substrate BSUB1 is prepared. The first base substrate BSUB1 may be a sapphire substrate Al₂O₃ or a silicon wafer including silicon. It should be understood, however, that the present disclosure is not limited thereto. According to one or more embodiments, the first base substrate BSUB1 is a sapphire substrate.

A plurality of semiconductor material layers SEM31L, SEM21L, SLT1L, MQW1L, EBL1L, and SEM11L is formed on the first base substrate BSUB1. The plurality of semiconductor material layers grown by the epitaxial method may be formed by growing a seed crystal. The method of forming the semiconductor material layers may include an electron beam deposition method, physical vapor deposition (PVD), chemical vapor deposition (CVD), plasma laser deposition (PLD), dual-type thermal evaporation, sputtering, metal-organic chemical vapor deposition (MOCVD), etc. Preferably, the method may be carried out by metal-organic chemical vapor deposition (MOCVD). It is, however, to be understood that the present disclosure is not limited thereto.

A precursor material for forming the plurality of semiconductor material layers SEM31L, SEM21L, SLT1L, MQW1L, EBL1L, and SEM11L is not particularly limited, and any typical material well known in the art may be selected as long as it can form a target material. For example, the precursor material may be a metal precursor including an alkyl group such as a methyl group or an ethyl group. For example, it may be, but is not limited to, a compound such as trimethyl gallium (Ga(CH₃)₃), trimethyl aluminum (Al(CH₃)₃), and/or triethyl phosphate ((C₂H₅)₃PO₄).

Specifically, the third semiconductor material layer SEM31L is formed on the first base substrate BSUB1. Although the third semiconductor material layer SEM31L is a single layer in the drawings, the present disclosure is not limited thereto. The third semiconductor layer SEM31L may include multiple layers. The third semiconductor material layer SEM31L may be disposed to reduce a lattice constant difference between the second semiconductor material layer SEM21L and the first base substrate BSUB1. For example, the third semiconductor material layer SEM31L may include an undoped semiconductor, and may be a material not doped into an n-type or p-type. In one or more embodiments, the third semiconductor material layer SEM31L may be, but is not limited to, at least one of undoped InAlGaN, GaN, AlGaN, InGaN, AlN, and/or InN.

The second semiconductor material layer SEM21L, the superlattice material layer SLT1L, the active material layer MQW1L, the electron blocking material layer EBL1L, and the first semiconductor material layer SEM11L are sequentially formed on the third semiconductor material layer SEM31L using the above-described method.

As described above with reference to FIGS. 16 to 23, a first light-emitting element stack S1 is grown on the first base substrate BSUB1, a second light-emitting element stack S2 is grown on the second base substrate BSUB2, and they are bonded together. In this manner, a plurality of light-emitting elements LE of the tandem structure can be formed.

Referring to FIG. 37, a third semiconductor material layer SEM32L, a second semiconductor material layer SEM22L, a superlattice material layer SLT2L, an active material layer MQW2L, an electron blocking material layer EBL2L, and a first semiconductor material layer SEM12L of the second light-emitting element stack S2 are sequentially formed on the base substrate BSUB1. Subsequently, the second semiconductor material layer SEM21L, the superlattice material layer SLT1L, the active material layer MQW1L, the electron blocking material layer EBL1L and the first semiconductor material layer SEM11L of the first light-emitting element stack S1 may be sequentially formed on the second light-emitting element S2.

The example shown in FIG. 37 where the second light-emitting element stack S2 and the first light-emitting element stack S1 are sequentially formed on the second base substrate BSUB2 is substantially identical to the method of fabricating the light-emitting element having the bonding layer BL except that the bonding layer BL is eliminated.

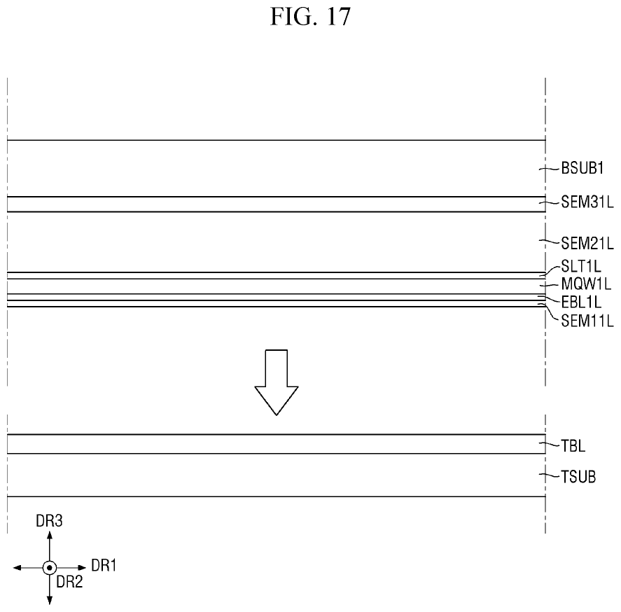

Subsequently, referring to FIG. 17, the first base substrate BSUB1 is attached to a temporary substrate TSUB (step S120 of FIG. 15).

Specifically, a temporary bonding layer TBL is formed on the temporary substrate TSUB, and the first base substrate BSUB1 is aligned on the temporary bonding layer TBL. In doing so, the first semiconductor material layer SEM11L from among the plurality of semiconductor material layers formed on the first base substrate BSUB1 is aligned such that it faces the temporary substrate TSUB. The temporary substrate TSUB may be made of a material that has mechanical stability to support the plurality of semiconductor material layers.

The temporary bonding layer TBL may be a material that is adhesive or detachable. The material that is adhesive or detachable may include urethane acrylate, epoxy acrylate, polyester acrylate, etc. The adhesive strength of the adhesive material may vary as ultraviolet (UV) light or heat is applied. Accordingly, the temporary bonding layer TBL allows the first semiconductor material layer SEM11L to be easily separated from the temporary substrate TSUB as required.

Subsequently, the first semiconductor material layer SEM11L formed on the first base substrate BSUB1 is brought into contact with the temporary substrate TSUB. In doing so, the first semiconductor material layer SEM11L is in contact with the temporary bonding layer TBL on the temporary substrate TSUB. Therefore, the temporary substrate TSUB and the first base substrate BSUB1 are temporarily attached together by the temporary bonding layer TBL.

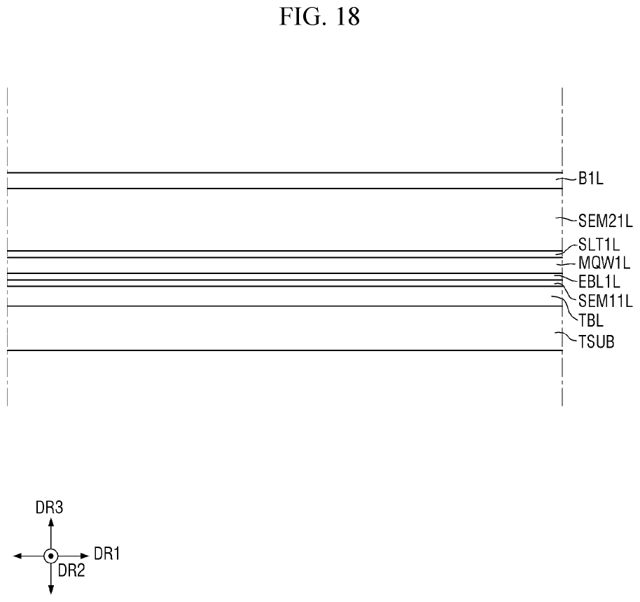

Subsequently, referring to FIG. 18, the first light-emitting element stack S1 having a first bonding layer B1L is formed (step S130 of FIG. 15).

The first light-emitting element stack S1 is formed by removing the first base substrate BSUB1 and the third semiconductor material layer SEM31L from among the plurality of semiconductor material layers disposed on the temporary substrate TSUB.

The process of separating the first base substrate BSUB1 may be carried out by using a laser lift-off (LLO) technique. The laser lift-off process uses a laser, and a KrF excimer laser (wavelength of 248 nm) may be used as the source. The energy density of the excimer laser is irradiated in the range of approximately 550 mJ/cm² to 950 mJ/cm², and the incident area may be in the range of 50×50 μm² to 1×1 cm². It should be understood, however, that the present disclosure is not limited thereto. As the laser is irradiated onto the first base substrate BSUB1, the first base substrate BSUB1 may be separated from the first light-emitting element stack S1.

The third semiconductor material layer SEM31L may be etched by spraying an etchant.

After the third semiconductor material layer SEM31L is removed, a material that is transparent and allows for oxidation bonding is deposited on the second semiconductor material layer SEM21L to form a first bonding layer B1L. Herein, the material that is transparent and allows for oxidation bonding may be ITO and/or IZO.

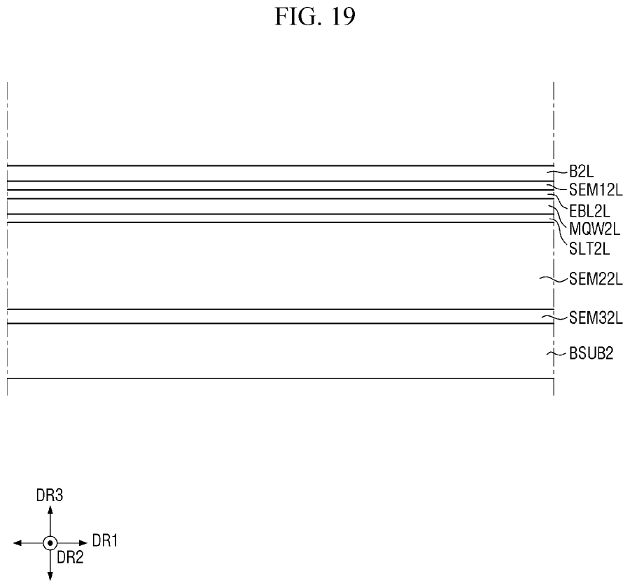

Subsequently, referring to FIG. 19, the second light-emitting element stack S2 having a second bonding layer B2L is formed on the second base substrate BSUB2 (step S140 of FIG. 15).

Initially, the second base substrate BSUB2 is prepared. The second base substrate BSUB2 may be a sapphire substrate Al₂O₃ or a silicon wafer including silicon. It should be understood, however, that the present disclosure is not limited thereto. According to one or more embodiments, the second base substrate BSUB2 is a sapphire substrate.

A plurality of semiconductor material layers SEM32L, SEM22L, SLT2L, MQW2L, EBL2L and SEM12L is formed on the second base substrate BSUB2. The plurality of semiconductor material layers grown by the epitaxial method may be formed by growing a seed crystal.

A precursor material for forming the plurality of semiconductor material layers SEM32L, SEM22L, SLT2L, MQW2L, EBL2L, and SEM12L is not particularly limited, and any typical material well known in the art may be selected as long as it can form a target material. For example, the precursor material may be a metal precursor including an alkyl group such as a methyl group or an ethyl group. For example, it may be, but is not limited to, a compound such as trimethyl gallium (Ga(CH₃)₃), trimethyl aluminum (Al(CH₃)₃), or triethyl phosphate ((C₂H₅)₃PO₄). The precursor material for forming the semiconductor material layers SEM32L, SEM22L, SLT2L, MQW2L, EBL2L, and SEM12L may be identical to the precursor material for forming the semiconductor material layers SEM31L, SEM21L, SLT1L, MQW1L, EBL1L and SEM11L. It should be understood, however, that the present disclosure is not limited thereto.

Specifically, the third semiconductor material layer SEM32L is formed on the second base substrate BSUB2. Although the third semiconductor material layer SEM32L is a single layer in the drawings, the present disclosure is not limited thereto. The third semiconductor layer SEM32L may include multiple layers. The third semiconductor material layer SEM32L may be disposed to reduce a lattice constant difference between the second semiconductor material layer SEM22L and the second base substrate BSUB2. For example, the third semiconductor material layer SEM32L may include an undoped semiconductor, and may be a material not doped into an n-type or p-type. In one or more embodiments, the third semiconductor material layer SEM32L may be, but is not limited to, at least one of undoped InAlGaN, GaN, AlGaN, InGaN, AlN, and/or InN.

The second semiconductor material layer SEM22L, the superlattice material layer SLT2L, the active material layer MQW2L, the electron blocking material layer EBL2L, and the first semiconductor material layer SEM12L are sequentially formed on the third semiconductor material layer SEM32L using the above-described method. Herein, the structure in which the third semiconductor material layer SEM32L, the second semiconductor material layer SEM22L, the superlattice material layer SLT2L, the active material layer MQW2L, the electron blocking material layer EBL2L, and the first semiconductor material layer SEM12L may be referred to as the second light-emitting element stack S2.

A material that is transparent and allows for oxidation bonding is deposited on the first semiconductor material layer SEM12L of the second light-emitting element stack S2 to form a second bonding layer B2L.

Herein, the material that is transparent and allows for oxidation bonding may be ITO and/or IZO.

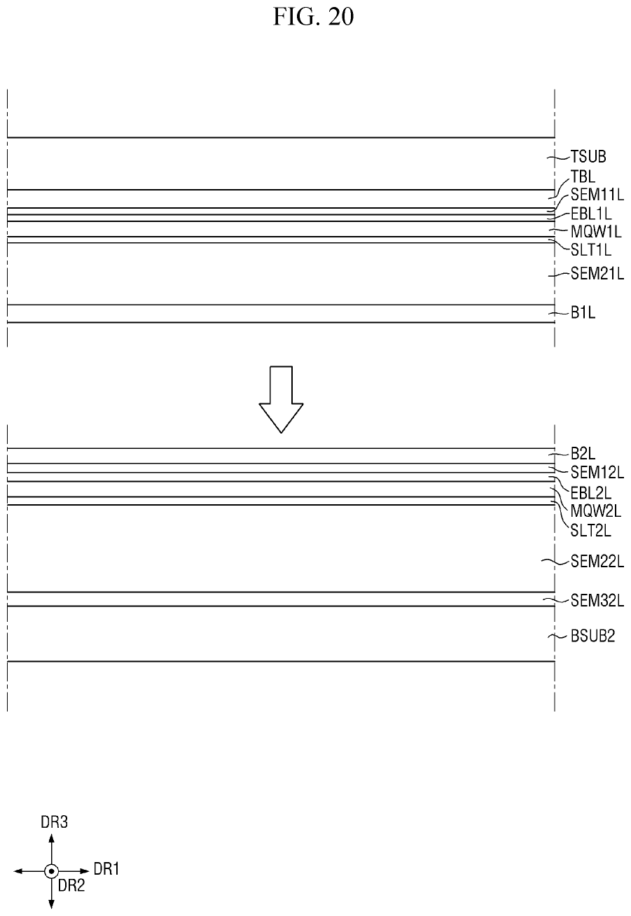

Subsequently, referring to FIGS. 20 to 23, light-emitting elements LE are formed by bonding the first bonding layer B1L to the second bonding layer B2L (step S150 of FIG. 15).

Specifically, the temporary substrate TSUB having the first light-emitting element stack S1 is aligned on the second base substrate BSUB2.

The second bonding layer B2L on the second base substrate BSUB2 is brought into contact with the first bonding layer B1L on the temporary substrate TSUB. The first light-emitting element stack S1 and the second light-emitting element stack S2 are bonded by oxide bonding the second bonding layer B2L with the first bonding layer B1L. The first bonding layer B1L and the second bonding layer B2L are bonded to each other by oxide bonding to form the bonding layer BL.

In this manner, a structure in which the second light-emitting element stack S2, the bonding layer BL, and the first light-emitting element stack S1 are sequentially stacked is formed on the second base substrate BSUB2.

A plurality of light emitting devices LE are formed by etching a plurality of semiconductor material layers of the structure in which the second light-emitting element stack S2, the bonding layer BL, and the first light-emitting element stack S1 are sequentially stacked.

A plurality of first mask patterns MP1 is formed above the structure in which the second light-emitting element stack S2, the bonding layer BL and the first light-emitting element stack S1 are sequentially stacked on the second base substrate BSUB2. The first mask patterns MP1 may be a hard mask including an inorganic material or a photoresist mask including an organic material. The first mask patterns MP1 prevent the second light-emitting element stack S2, the bonding layer BL, and the first light-emitting element stack S1 thereunder from being etched. Subsequently, parts of the second light-emitting element stack S2, the bonding layer BL, and the first light-emitting element stack S1 are etched using the plurality of first mask patterns MP1 as a mask (1st etch), thereby forming a plurality of light emitting elements LE.

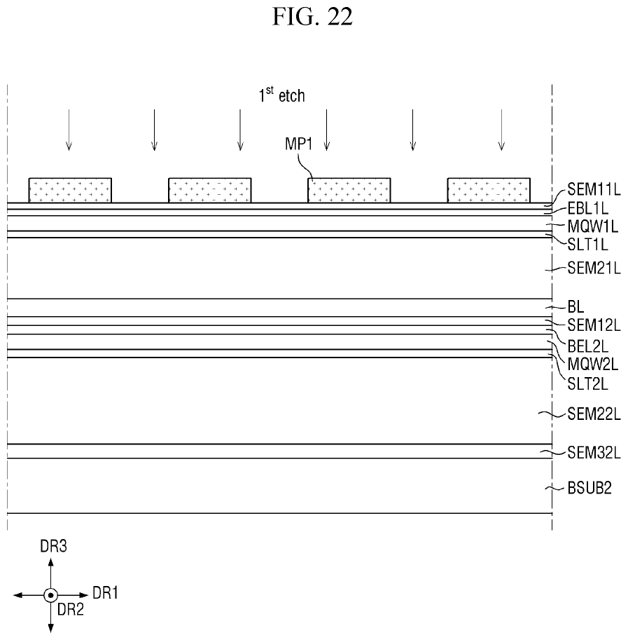

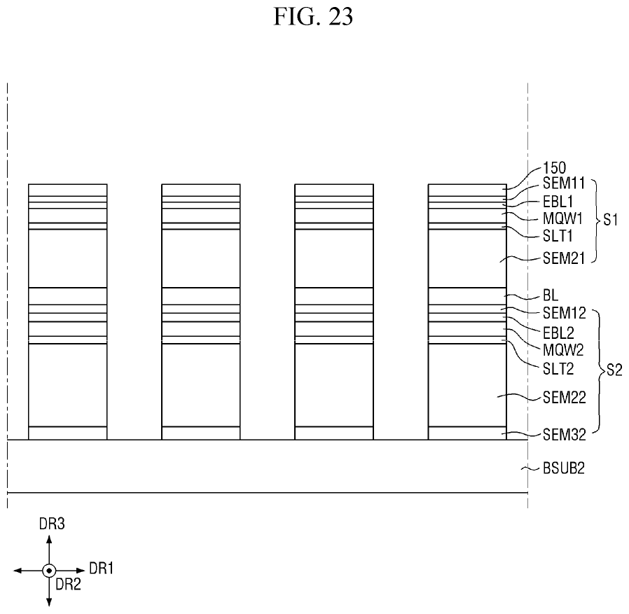

As shown in FIGS. 22-23, on the second base substrate BSUB2, parts of the second light-emitting element stack S2, the bonding layer BL, and the first light-emitting element stack S1 that do not overlap with the first mask patterns MP1 are etched and removed, while parts of them that overlap with the first mask pattern MP1 are not etched and thus may be formed as a plurality of light-emitting elements LE.

The second light-emitting element stack S2, the bonding layer BL, and the first light-emitting element stack S1 may be etched by a technique known in the art. For example, the process of etching the second light-emitting element stack S2, the bonding layer BL, and the first light-emitting element stack S1 may include dry etching, wet etching, reactive ion etching (RIE), deep reactive ion etching (DRIE), inductively-coupled-plasma reactive ion etching (ICP-RIE), etc. The dry etching allows for anisotropic etching, and thus it may be suitable for vertical etching. When any of the above-described etching methods is used, the etchant may be Cl₂ or O₂. It is, however, to be understood that this is merely illustrative.

The parts of the second light-emitting element stack S2, the bonding layer BL, and the first light-emitting element stack S1, which overlap with the first mask pattern MP1 are not etched and formed into a plurality of light-emitting elements LE. Accordingly, the plurality of light-emitting elements LE is formed, including the second light-emitting element stack S2, the bonding layer BL, and the first light-emitting element stack S1. The second light-emitting element stack S2 may be formed, including the third semiconductor layer SEM32, the second semiconductor layer SEM22, the superlattice layer SLT2, the active layer MQW2, the electron blocking layer EBL2, and the first semiconductor layer SEM12. The first light-emitting element stack S1 may be formed, including the second semiconductor layer SEM21, the superlattice layer SLT1, the active layer MQW1, the electron blocking layer EBL1, and the first semiconductor layer SEM11.

Subsequently, the connection electrodes 150 are formed on the plurality of light-emitting elements LE by stacking connection electrode material layers on the second base substrate BSUB2 and etching them. For example, a reflective layer material layer and a connection layer material layer are sequentially stacked on the base substrate BSUB, and they are etched altogether, such that the connection electrode 150 including the reflective layer and the connection layer may be formed. The connection electrode 150 may be formed directly on the upper surface of the first light-emitting element stack S1 of the light-emitting element LE. The connection electrode 150 may be formed directly on the upper surface of the first semiconductor layer SEMI 1 of the first light-emitting element stack S1. According to one or more embodiments, a reflective layer 151 (e.g., see FIG. 6) of the connection electrode 150 may be in direct contact with the upper surface of the first semiconductor layer SEMI 1 of the first light-emitting element stack S1 of the connection electrode 150. The light-emitting element LE may include the connection electrode 150.

Subsequently, the plurality of light-emitting elements LE of the second base substrate BSUB2 are moved and attached to the transfer film LFL1, and the transfer film LFL1 is elongated (step S200 of FIG. 14).

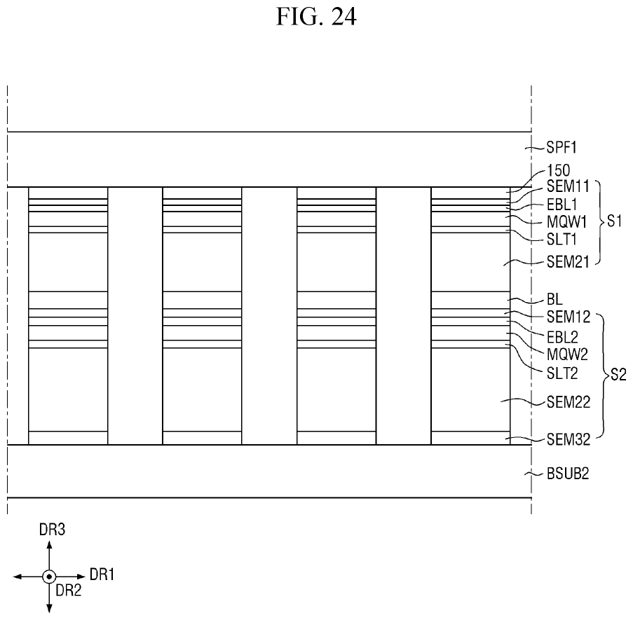

Specifically, referring to FIG. 24, a support film SPF1 is attached on the plurality of light-emitting elements LE of the second base substrate BSUB2.

The support film SPF1 may be aligned on the plurality of light-emitting elements LE and attached to the connection electrodes 150 of the plurality of light-emitting elements LE.

The support film SPF1 may include a support layer and an adhesive layer disposed on the support layer. The support layer may be made of a material that is transparent and has mechanical stability to allow light to pass therethrough. For example, the support layer may include a transparent polymer such as polyester, polyacrylic, polyepoxy, polyethylene, polystyrene, polyethylene terephthalate, etc. The adhesive layer may include an adhesive material for bonding the light-emitting elements LE. For example, the adhesive material may include urethane acrylate, epoxy acrylate, polyester acrylate, etc. The adhesive material may be a material whose adhesive strength changes as ultraviolet (UV) light or heat is applied, and thus the adhesive layer can be easily separated from the light-emitting elements LE.

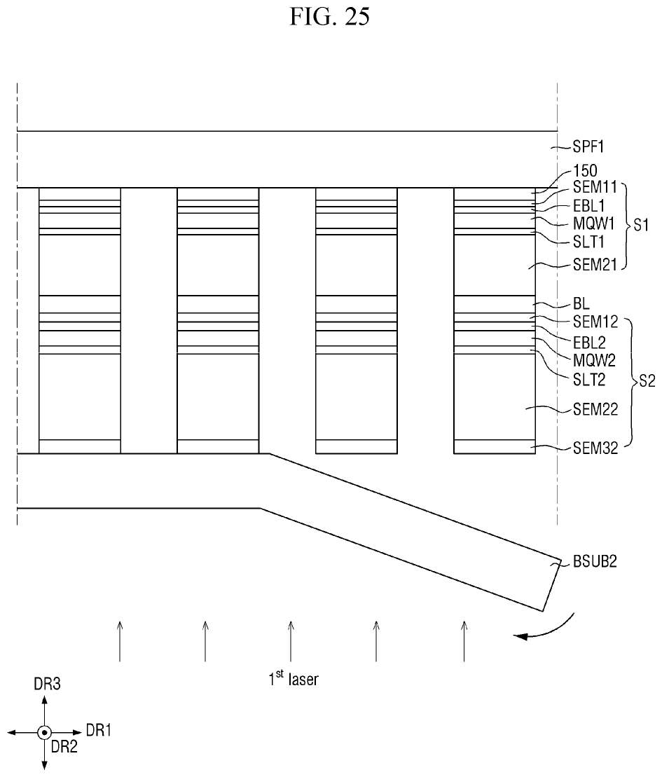

Subsequently, referring to FIG. 25, the second base substrate BSUB2 is separated by irradiating it with a laser (1st laser). The second base substrate BSUB2 is separated from the third semiconductor layers SEM32 of the plurality of light-emitting elements LE. The process of separating the second base substrate BSUB2 is substantially identical to the above-described process of separating the first base substrate BSUB1; and, therefore, the redundant descriptions will be omitted.

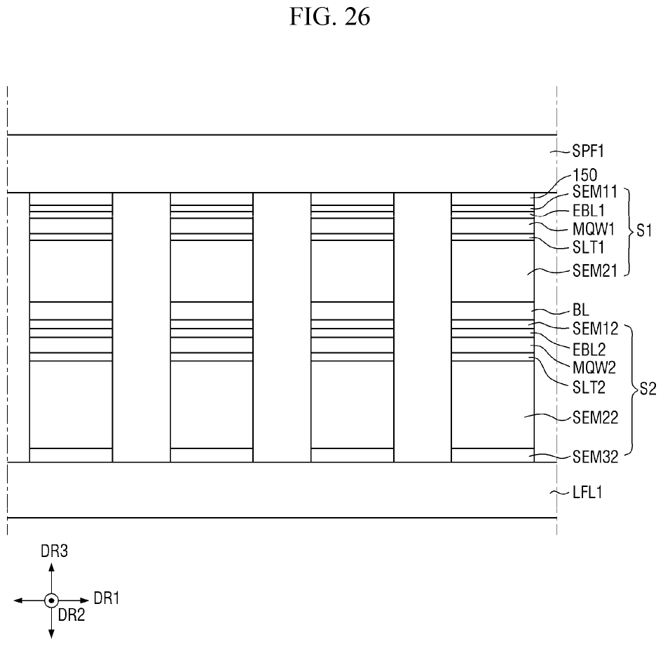

Referring to FIG. 26, the transfer film LFL1 is attached to the plurality of light-emitting elements LE after the second base substrate BSUB2 has been separated.

Specifically, the transfer film LFL1 is attached to the third semiconductor layer SEM32 of each of the plurality of light-emitting elements LE. The transfer film LFL1 may be aligned on the plurality of light-emitting elements LE and may be attached to the third semiconductor layers SEM32 of the plurality of light-emitting elements LE.

The transfer film LFL1 may include a stretchable material. Examples of the stretchable material may include, for example, polyolefine, polyvinyl chloride (PVC), elastomeric silicone, elastomeric polyurethane, elastomeric polyisoprene, etc. Like the support film SPF1 described above, the transfer film LFL1 may also include a support layer and an adhesive layer to adhere and support the light-emitting elements LE.

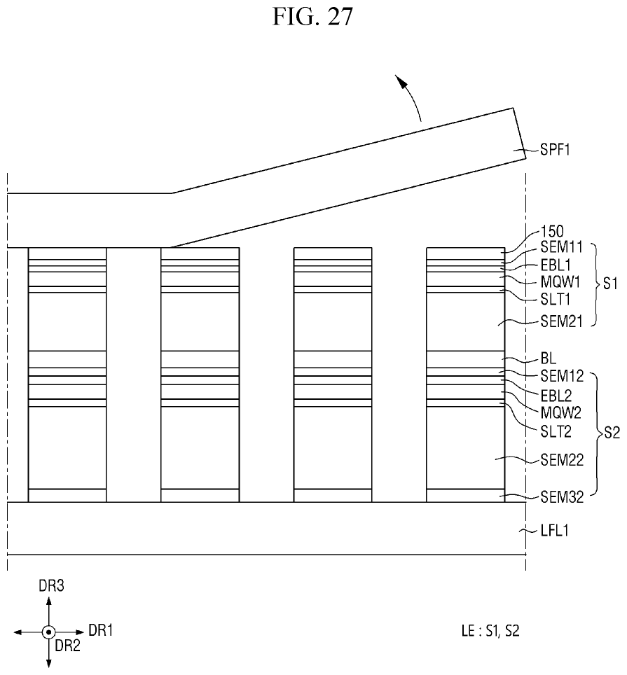

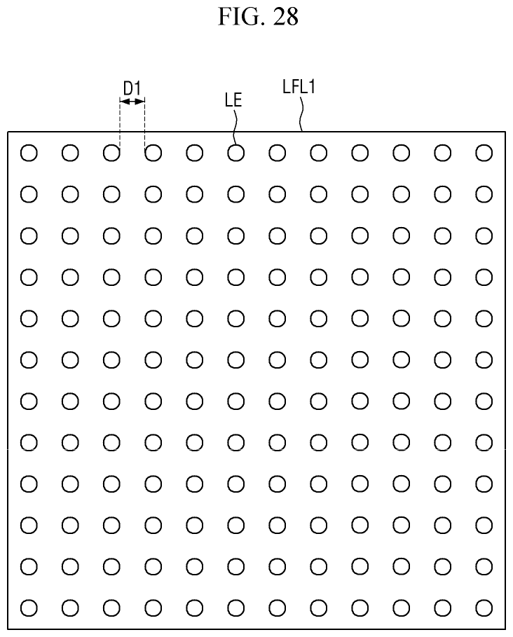

Referring to FIGS. 27 and 28, the support film SPF1 is separated from the light-emitting elements LE. By applying ultraviolet ray or heat to the support film SPF1 to reduce the adhesive strength of the adhesive layer of the support film SPF1, the support film SPF1 may be physically or naturally detached therefrom. The plurality of light-emitting elements LE may be spaced apart one another by a first distance D1 on the transfer film LFL1 and may be arranged in a dot pattern.

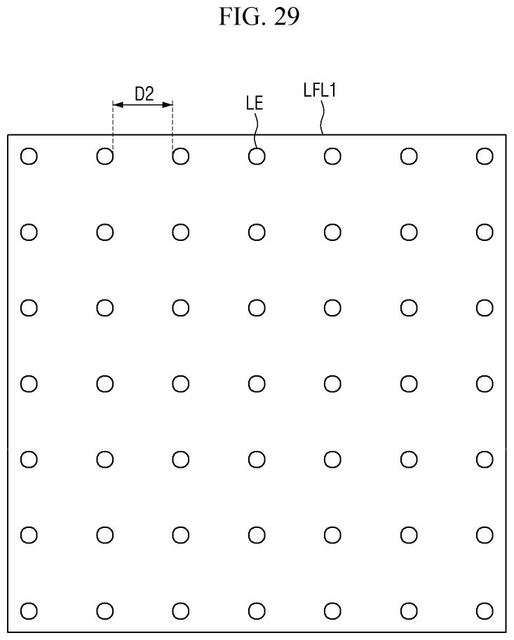

Subsequently, referring to FIG. 29, the first transfer film LFL1 is elongated (1st ORI). The transfer film LFL1 may be elongated two-dimensionally, including in the first direction DR1 and the second direction DR2. As the transfer film LFL1 is elongated, the plurality of light-emitting elements LE attached to the transfer film LFL1 may be spaced from one another by a second distance D2. The plurality of light-emitting elements LE may be uniformly spaced from one another by the second distance D2 greater than the first distance Dl.

The stretching strength (or tensile strength) of the transfer film LFL1 may be adjusted depending on the desired second distance D2 of the light-emitting elements LE, for example, approximately 120 gf/inch. It should be understood, however, that the present disclosure is not limited thereto. The stretching strength (or tensile strength) may be adjusted according to the second distance D2.

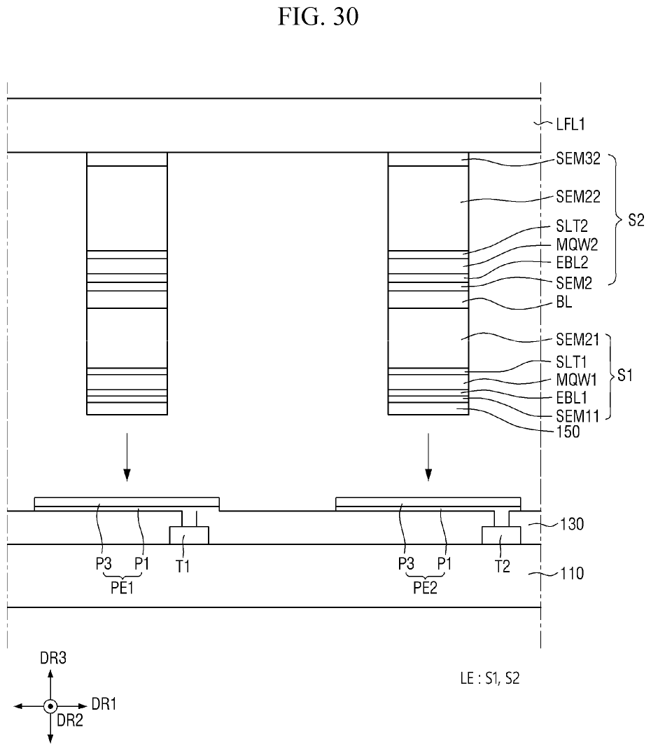

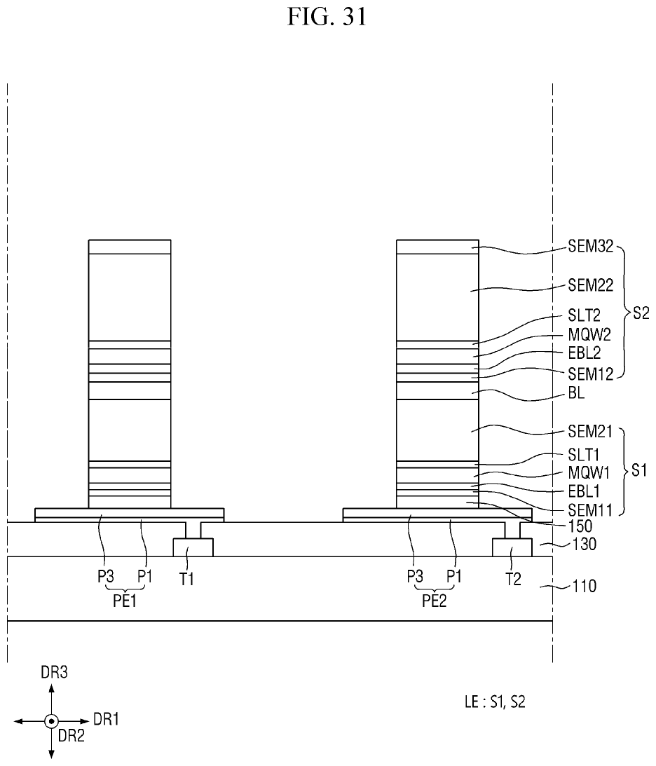

Subsequently, referring to FIGS. 30 and 31, the transfer film LFL1 is attached to the first substrate 110 to attach the plurality of light-emitting elements LE onto the first substrate 110, and the transfer film LFL1 is removed (step S300 in FIG. 14).

Specifically, the transfer film LFL1 is aligned on the first substrate 110. In doing so, the connection electrodes 150 of the light-emitting elements LE arranged on the transfer film LFL1 are aligned so that they are oriented toward the first substrate 110.

Specifically, the first substrate 110 and the transfer film LFL1 are attached together. Specifically, the connection electrodes 150 of the light-emitting elements LE arranged on the transfer film LFL1 are brought into contact with an upper electrode material layer P3 of the pixel electrodes PE1 and PE2 of the first substrate 110. At this time, the connection electrodes 150 of the light-emitting elements LE are in contact with the upper electrode material layer P3. Subsequently, the first substrate 110 and the transfer film LFL1 are attached together by fusion bonding the connection electrodes 150 of the light-emitting elements LE with the upper electrode material layer P3. At this time, the plurality of light-emitting elements LE is attached to the upper surface of the upper electrode material layer P3. For fusion bonding, a laser may be irradiated onto the upper electrode material layer P3 from above the transfer substrate LFL1. After the laser is irradiated onto the upper electrode material layer P3, high heat of the laser is conducted to the upper electrode material layer P3, so that the interface with the first connection electrodes 150 of the light-emitting elements LE can be attached. In particular, because the upper electrode material layer P3 is made of copper (Cu) having excellent thermal conductivity, adhesive properties with the connection electrodes 150 of the light-emitting elements LE may be excellent. A yttrium aluminum garnet (YAG) laser may be used as the source of laser used for the fusion bonding.

Subsequently, the transfer film LFL1 is separated from the plurality of light-emitting elements LE. By applying ultraviolet ray or heat to the transfer film LFL1 to reduce the adhesive strength of the adhesive layer of the transfer film LFL1, the transfer film LFL1 may be physically and/or naturally detached therefrom.

Accordingly, a plurality of light-emitting elements LE may be randomly arranged on the pixel electrode layers PE1 and PE2.

A planarization layer PLL is formed on the insulating layer 130 and each of the pixel electrodes PE1 and PE2, and a common electrode CE is formed on the planarization layer PLL (step S400 of FIG. 14).

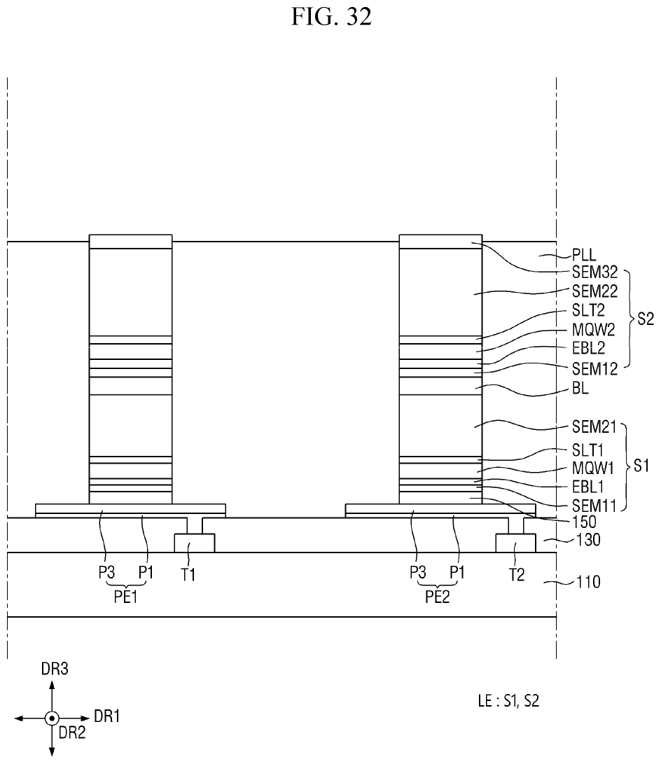

Referring to FIG. 32, the planarization layer PLL is formed by applying an organic material over the first substrate 110. The planarization layer PLL is formed to have a thickness smaller than the height of the light-emitting element LE so that the third semiconductor layer SEM32 of the second light-emitting element stack S2 of the light-emitting element LE is exposed.

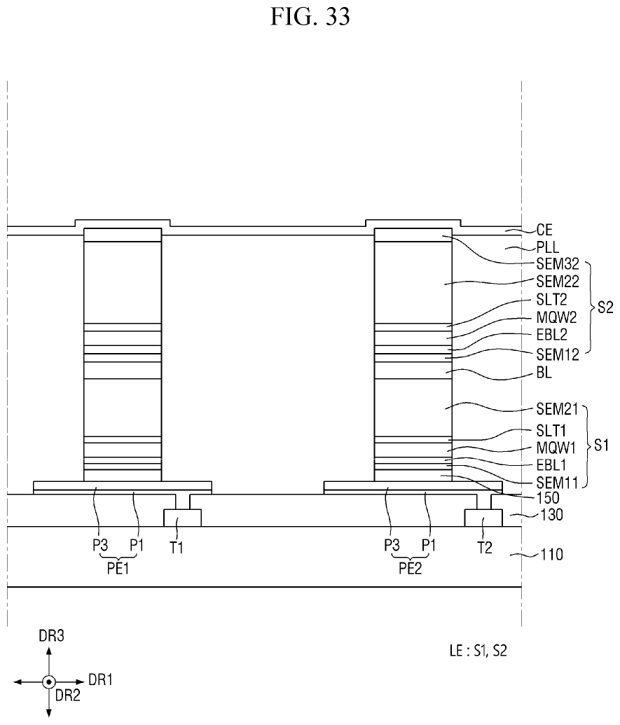

Subsequently, referring to FIG. 33, the common electrode CE is formed by depositing a transparent conductive material on the planarization layer PLL. The common electrode CE is formed to cover the light-emitting elements LE and the planarization layer PLL. The common electrode CE is in contact with the third semiconductor layer SEM32 of the second light-emitting element stack S2 of the light-emitting element LE that is exposed from the planarization layer PLL.

Subsequently, partition walls PW including a plurality of openings OP1 are formed on the common electrode CE (step S500 of FIG. 14).

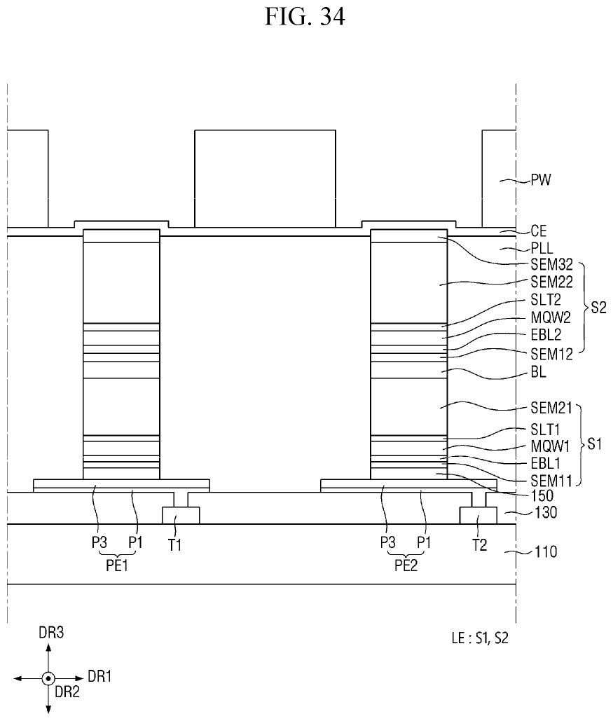

Referring to FIG. 34, an organic material is applied onto the first substrate 110 including the common electrode CE and is patterned, to form the partition walls PW. A plurality of openings, for example, the first opening OP1 is formed in line with the first emission area EA1, and the second opening OP2 is formed in line with the second emission area EA2 (e.g., see FIG. 5). In one or more embodiments, other openings may be formed in line with other emission areas, respectively.

Subsequently, wavelength conversion layers QDL are formed in a plurality of openings OP1, respectively. (step S600 of FIG. 14).

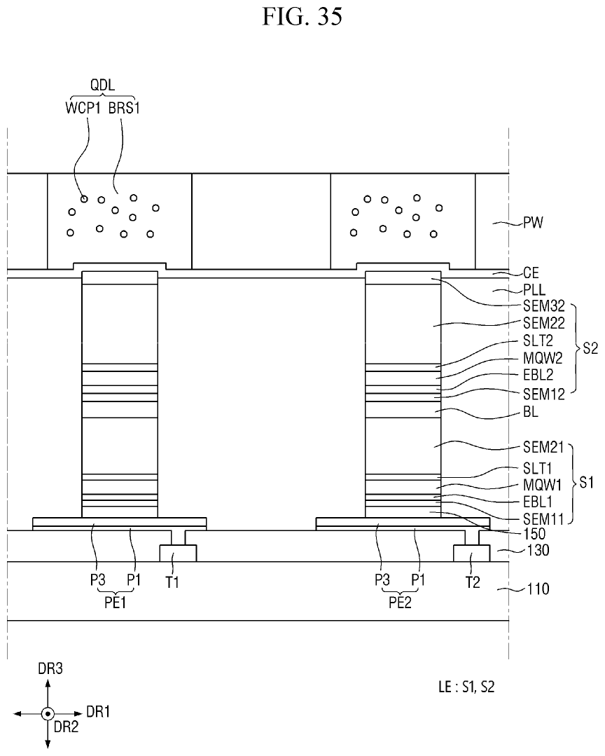

Referring to FIGS. 34-35, the plurality of openings OP1 may be filled with the wavelength conversion layers QDL, respectively. The wavelength conversion layers QDL may be formed by a solution process such as inkjet printing and imprinting with a solution in which the first wavelength-converting particles WCP1 are mixed in a first base resin BRS1, but the present disclosure is not limited thereto. The wavelength conversion layers QDL may be formed in the plurality of openings OP1, respectively, and may be formed to overlap the plurality of emission areas EA1.

Subsequently, a color filter CF1 and a light-blocking member BK are formed on the wavelength conversion layer QDL (step S700 of FIG. 14).

Referring to FIG. 35, the light-blocking member BK is formed on the partition walls PW. The light-blocking member BK is formed by applying a light-blocking material and patterning it. The light-blocking member BK may overlap the non-emission area NEA but not with the emission areas EA1 and EA2.

Subsequently, the color filter CF1 is formed on the wavelength conversion layer QDL partitioned by the light-blocking member BK. The color filter CF1 may be formed via a photolithography process. The color filter CF1 may have, but is not limited to, a thickness of 1 μm or less.

Specifically, a first color filter material layer is applied onto the partition wall PW and the wavelength conversion layer QDL and patterned via the photo process, to form the first color filter CF1 overlapping the first opening OP1. Likewise, other color filters are also formed to overlap the openings via a patterning process.

Subsequently, a protective layer PTL is formed on the light-blocking member BK and the color filter CF1, such that a display device 10 according to one or more embodiments is fabricated.

As described above with reference to FIGS. 16 to 37, the display device 10 according to one or more embodiments include the light-emitting elements LE each having the tandem structure in which the first light-emitting element stack S1 and the second light-emitting element stack S2 are stacked in the third direction. Accordingly, even if there is a short circuit in one of the upper and lower light-emitting element stacks of a light-emitting element, the light-emitting element can still emit light. Therefore, no repair is required for a light-emitting element in which a short circuit is created.

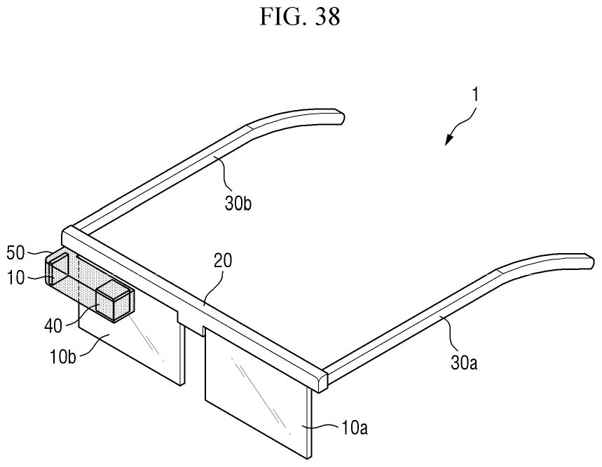

FIG. 38 is an example diagram illustrating a virtual reality device including a display device according to one or more embodiments. FIG. 38 illustrates a virtual reality device 1 in which the display device 10 according to an embodiment is used.

Referring to FIG. 38, the virtual reality device 1 according to one or more embodiments may be a device in a form of glasses. The virtual reality device 1 according to one or more embodiments may include a display device 10, a left-eye lens 10a, a right-eye lens 10b, a support frame 20, left and right legs 30a and 30b, a reflective member 40, and a display device housing 50.

FIG. 38 illustrates the virtual reality device 1 including the two legs 30a and 30b. However, the present disclosure is not limited thereto. The virtual reality device 1 according to one or more embodiments may be used in a head-mounted display including a head-mounted band that may be mounted on a head instead of the legs 30a and 30b. For example, the virtual reality device 1 according to one or more embodiments may not be limited to the example shown in FIG. 38, and may be applied in various forms and in various electronic devices.

The display device housing 50 may receive the display device 10 and the reflective member 40. An image displayed on the display device 10 may be reflected from the reflective member 40 and provided to a user's right eye through the right-eye lens 10b. Thus, the user may view a virtual reality image displayed on the display device 10 via the right eye.

FIG. 38 illustrates that the display device housing 50 is disposed at a right end of the support frame 20. However, the present disclosure is not limited thereto. For example, the display device housing 50 may be disposed at a left end of the support frame 20. In this case, the image displayed on the display device 10 may be reflected from the reflective member 40 and provided to the user's left eye via the left-eye lens 10a. Thus, the user may view the virtual reality image displayed on the display device 10 via the left eye. As another example, the display device housing 50 may be disposed at each of the left end and the right end of the support frame 20. In this case, the user may view the virtual reality image displayed on the display device 10 via both the left eye and the right eye.

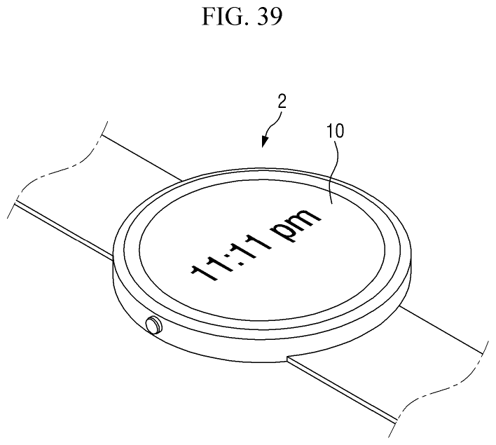

FIG. 39 is an example diagram illustrating a smart device including a display device according to one or more embodiments.

Referring to FIG. 39, a display device 10 according to one or more embodiments may be applied to a smart watch 2 as one of smart devices.

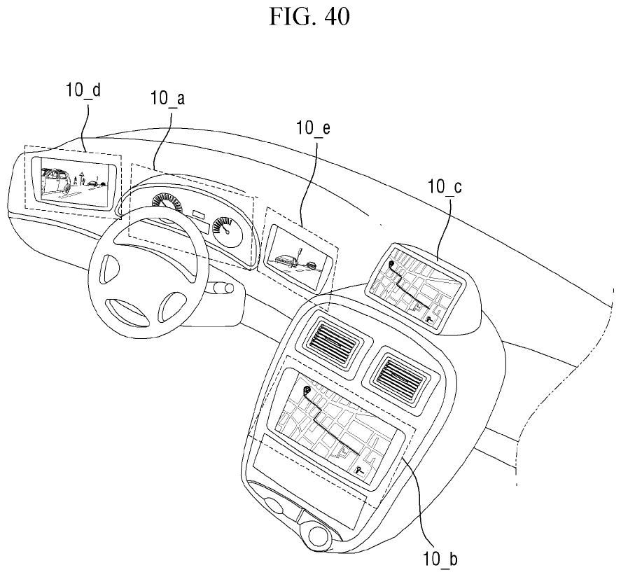

FIG. 40 is an example diagram illustrating a vehicle including a display device according to one or more embodiments. FIG. 40 illustrates a vehicle in which display devices according to one or more embodiments are used.

Referring to FIG. 40, the display devices 10_a, 10_b, and 10_c according to one or more embodiments may be applied to the dashboard of the vehicle, applied to the center fascia of the vehicle, or applied to a center information display(CID) disposed on the dashboard of the vehicle. Further, each of the display devices 10_d and 10_e according to one or more embodiments may be applied to each room mirror display that replaces each of side-view mirrors of the vehicle.

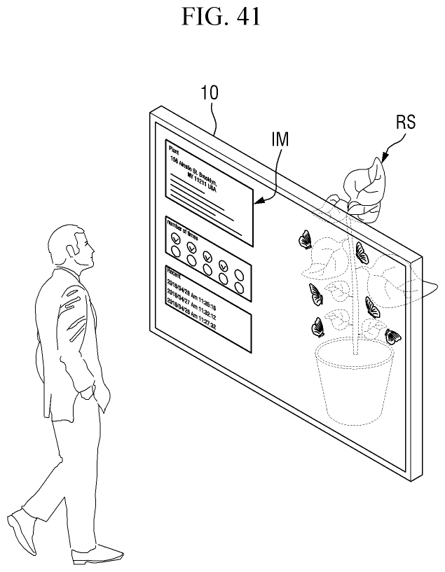

FIG. 41 is an example diagram illustrating a transparent display device including a display device according to one or more embodiments.

Referring to FIG. 41, a display device according to one or more embodiments may be applied to a transparent display device. The transparent display device may transmit light therethrough while displaying an image IM thereon. Therefore, a user located in front of the transparent display device may not only view the image IM displayed on the display device 10, but also view an object RS or a background located in rear of the transparent display device. In case that the display device 10 is applied to the transparent display device, the first substrate 110 of the display device 10 shown in FIG. 5 may include a light transmitting portion that may transmit light therethrough or may be made of a material that may transmit light therethrough.

In concluding the detailed description, those skilled in the art will appreciate that many variations and modifications can be made to the embodiments without substantially departing from the principles and scope of the present disclosure. Therefore, the embodiments of the present disclosure are used in a generic and descriptive sense only and not for purposes of limitation.

What is claimed is:

1. A display device comprising:
pixel electrodes on a substrate;
light-emitting elements on the pixel electrodes;
a planarization layer on the pixel electrodes to fill a space between the light-emitting elements; and
a common electrode on the planarization layer and the light-emitting elements,
wherein each of the light-emitting elements comprises a first light-emitting element stack and a second light-emitting element stack on the first light-emitting element stack.

2. The display device of claim 1, further comprising:
a bonding layer between the first light-emitting element stack and the second light-emitting element stack.

3. The display device of claim 2, wherein the bonding layer comprises indium tin oxide (ITO) or indium zinc oxide (IZO).

4. The display device of claim 1, wherein the first light-emitting element stack comprises a first semiconductor layer, an electron blocking layer, an active layer, a superlattice layer, and a second semiconductor layer, and
wherein the second light-emitting element stack comprises a first semiconductor layer, an electron blocking layer, an active layer, a superlattice layer, a second semiconductor layer and a third semiconductor layer.

5. The display device of claim 4, wherein the second semiconductor layer of the first light-emitting element stack is in contact with the first semiconductor layer of the second light-emitting element stack.

6. The display device of claim 1, wherein the light-emitting elements are randomly arranged on the pixel electrodes.

7. The display device of claim 5, further comprising:
a wavelength-converting portion on the common electrode,
wherein the wavelength-converting portion comprises:
partition walls partitioning emission areas and a non-emission area;
a wavelength conversion layer between the partition walls and overlapping with the emission areas;
a light-blocking member on the partition walls; and
color filters on the wavelength conversion layer.

8. The display device of claim 7, further comprising:
a reflective metal layer between the common electrode and the partition walls,
wherein the reflective metal layer overlaps with the non-emission area.

9. A display device comprising:
pixel electrodes on a substrate;
light-emitting elements on the pixel electrodes;
a planarization layer on the pixel electrodes to fill between the light-emitting elements; and
a common electrode on the planarization layer and the light-emitting elements,
wherein the light-emitting elements have a tandem structure in which a plurality of light-emitting element stacks is stacked, and
wherein each of the plurality of light-emitting element stacks comprises a first semiconductor layer, an electron blocking layer, an active layer, a superlattice layer, and a second semiconductor layer.

10. The display device of claim 9, further comprising:
a bonding layer between the plurality of light-emitting element stacks.

11. The display device of claim 10, wherein the bonding layer comprises indium tin oxide (ITO) or indium zinc oxide (IZO).

12. The display device of claim 9, wherein the second semiconductor layer of a light-emitting element stack from among the plurality of light-emitting element stacks at a bottom is in contact with the first semiconductor layer of the light-emitting element stack at a top.

13. The display device of claim 9, wherein a top light-emitting element stack from among the plurality of light-emitting element stacks further comprises a third semiconductor layer.

14. A method of fabricating a display device, the method comprising:
forming light-emitting elements on a base substrate;
attaching the light-emitting elements onto pixel electrodes by bonding a substrate comprising the pixel electrodes to the base substrate;
separating the base substrate from the light-emitting elements by irradiating a laser beam onto the base substrate;
forming a planarization layer between the pixel electrodes and the light-emitting elements; and
forming a common electrode on the planarization layer,
wherein the light-emitting elements comprise a first light-emitting element stack and a second light-emitting element stack on the first light-emitting element stack.

15. The method of claim 14, wherein the forming the light-emitting elements on the base substrate comprises:
forming a plurality of semiconductor material layers on a first base substrate;
attaching the first base substrate to a temporary substrate;
forming the first light-emitting element stack by separating the first base substrate from the plurality of semiconductor material layers;
forming a first bonding layer on the first light-emitting element stack;
forming the second light-emitting element stack by forming a plurality of semiconductor material layers on a second base substrate;
forming a second bonding layer on the second light-emitting element stack;
stacking the first light-emitting element stack on the second light-emitting element stack such that the first bonding layer and the second bonding layer are in contact with each other, and bonding the first bonding layer and the second bonding layer to each other;
separating the temporary substrate from the first light-emitting element stack; and
forming the light-emitting elements by patterning the first light-emitting element stack stacked on the second light-emitting element stack using a photoresist pattern.

16. The method of claim 15, further comprising:
forming a connection electrode on the light-emitting elements.

17. The method of claim 15, wherein the forming the plurality of semiconductor material layers on the first base substrate comprises:
forming a third semiconductor material layer, a second semiconductor material layer, a superlattice material layer, an active material layer, an electron blocking material layer, and a first semiconductor material layer on the first base substrate in this order.

18. The method of claim 17, wherein the forming the first light-emitting element stack by separating the first base substrate from the plurality of semiconductor material layers comprises:
irradiating the base substrate with a laser, separating the first base substrate from the plurality of semiconductor material layers, and etching the third semiconductor material layer to remove it.

19. The method of claim 15, wherein the forming the second light-emitting element stack by forming the plurality of semiconductor material layers on the second base substrate comprises:
forming a third semiconductor material layer, a second semiconductor material layer, a superlattice material layer, an active material layer, an electron blocking material layer, and a first semiconductor material layer on the second base substrate in this order.

20. The method of claim 15, wherein the stacking the first light-emitting element stack on the second light-emitting element stack such that the first bonding layer and the second bonding layer are in contact with each other, and bonding the first bonding layer and the second bonding layer to each other comprises:
oxide bonding the first bonding layer and the second bonding layer to each other.

21. The method of claim 14, wherein the forming the light-emitting elements on the base substrate comprises:
forming a third semiconductor material layer, a second semiconductor material layer, a superlattice material layer, an active material layer, an electron blocking material layer, and a first semiconductor material layer of a second light-emitting element stack on the base substrate in this order;
forming a third semiconductor material layer, a second semiconductor material layer, a superlattice material layer, an active material layer, an electron blocking material layer, and a first semiconductor material layer of the first light-emitting element stack on the second light-emitting element stack; and
forming the light-emitting elements by patterning the second light-emitting element stack and the first light-emitting element stack using a photoresist pattern.
